(19) United States
(12) Patent Application Publication
(10) Pub. No.: US 2023/0230413 A1
(43) Pub. Date: Jul. 20, 2023

(54) ELECTRONIC DEVICE

(71) Applicant: SONY SEMICONDUCTOR SOLUTIONS CORPORATION, Kanagawa (JP)

(72) Inventor: Shinichiro NOUDO, Kumamoto (JP)

(73) Assignee: SONY SEMICONDUCTOR SOLUTIONS CORPORATION, Kanagawa (JP)

(21) Appl. No.: 18/001,757

(22) PCT Filed: Jun. 11, 2021
(86) PCT No.: PCT/JP2021/022296

§ 371 Date: Dec. 14, 2022

(30) Foreign Application Priority Data
Jun. 25, 2020 (JP) 2020-109980

(51) Int. Cl. G06V 40/13; G06V 10/147; H10K 59/40; H10K 59/80

(52) U.S. Cl. CPC G06V 40/1318; G06V 10/147; H10K 59/40; H10K 59/8792

(57) ABSTRACT

Provided is an electronic device capable of suppressing an influence of internal reflected light in a device. An electronic device is provided with, sequentially from one side to the other side, a first polarizing plate that makes incident light linearly polarized light, a first ¼ wavelength plate a slow axis of which is different from an absorption axis of the first polarizing plate by 45 degrees or 135 degrees, a self-luminous element layer, a second ¼ wavelength plate a slow axis of which is in the same direction as the slow axis of the first ¼ wavelength plate, a second polarizing plate an absorption axis of which is orthogonal to the absorption axis of the first polarizing plate, and an imaging device that images light via the second polarizing plate.

### TECHNICAL FIELD

The present disclosure relates to an electronic device.

### BACKGROUND ART

Optical fingerprint sensors are increasingly mounted on electronic devices such as smartphones, mobile phones, and personal computers (PCs). The optical fingerprint sensor, for example, irradiates a surface of a finger with light to image for a necessary operation specification or event such as sleep mode release, extracts a feature of a fingerprint from an acquired image, collates the same with information stored in advance, and determines whether or not this is a registered person. Moreover, in order to prevent impersonation, biometric authentication such as skin color spectrum, vein information, and blood flow pulsation may be combined. However, in such fingerprint authentication and biometric authentication, there is a possibility that authentication accuracy is deteriorated due to noise light generated from other than a subject. There are roughly two types of noise light: external noise caused by light from outside a display, and internal noise in which light emission when imaging the subject is reflected and scattered in the electronic device without passing through the subject and is sensed by an imaging device.

Regarding the external noise, for example, an image without irradiation and an image with irradiation are acquired, and a noise influence may be removed by difference processing (refer to Patent Document 3). However, the internal noise due to the reflection and scattering in the electronic device caused by illumination light cannot be corrected in principle by the method disclosed in Patent Document 3.

### CITATION LIST

### Patent Document

Patent Document 1: WO 2016/114154
Patent Document 2: Japanese Patent Application Laid-Open No. 2018-033505
Patent Document 3: Japanese Patent Application Laid-Open No. 2009-277054

### SUMMARY OF THE INVENTION

### Problems to be Solved by the Invention

One aspect of the present disclosure provides an electronic device capable of suppressing an influence of internal reflected light in a device.

### Solutions to Problems

In order to solve the above-described problem, the present disclosure provides

an electronic device provided with:

sequentially from one side to the other side,

a first polarizing plate that makes incident light linearly polarized light;

a first ¼ wavelength plate a slow axis of which is different from an absorption axis of the first polarizing plate by 45 degrees or 135 degrees;

a self-luminous element layer;

a second ¼ wavelength plate a slow axis of which is in the same direction as the slow axis of the first ¼ wavelength plate;

a second polarizing plate an absorption axis of which is orthogonal to the absorption axis of the first polarizing plate; and

an imaging device that images light via the second polarizing plate.

In order to solve the above-described problem, the present disclosure provides

an electronic device provided with:

sequentially from one side to the other side,

a first polarizing plate that makes incident light linearly polarized light;

a first ¼ wavelength plate a slow axis of which is different from an absorption axis of the first polarizing plate by 45 degrees or 135 degrees;

a self-luminous element layer;

a second ¼ wavelength plate a slow axis of which is different from the slow axis of the first ¼ wavelength plate by 90 degrees;

a second polarizing plate an absorption axis of which is in the same direction as the absorption axis of the first polarizing plate; and

an imaging device that images light via the second polarizing plate.

The second polarizing plate may be provided in a pixel structure of the imaging device.

The self-luminous element layer may be a display including a self-luminous element,

the imaging device may be an imaging device that images scattered light of a finger irradiated with light of the self-luminous element via the first ¼ wavelength plate and the first polarizing plate, and may image the scattered light of the finger as a fingerprint image via the first polarizing plate, the first ¼ wavelength plate, the self-luminous element layer, the second ¼ wavelength plate, and the second polarizing plate, and

the electronic device may further include:

a signal processing unit that extracts a feature point from the fingerprint image;

a storage unit that stores a feature point of a fingerprint of an authentication target; and

an authentication unit that collates the feature point extracted from the fingerprint image with the feature point of the fingerprint of the authentication target to determine whether or not the feature points coincide with each other.

The imaging device may be an imaging device that images an authentication target irradiated with light of the self-luminous element layer via the first ¼ wavelength plate and the first polarizing plate, and may image light from the authentication target via the first polarizing plate, the first ¼ wavelength plate, the self-luminous element layer, the second ¼ wavelength plate, and the second polarizing plate,

the imaging device may output an image signal on the basis of incident light incident via an optical member with a different transmission characteristic of a wavelength, and

the electronic device may further include an authentication unit that determines that an imaging target is an artifact in a case where there is no rise in a wavelength region of 500 to 600 nanometers.

The imaging device may be an imaging device that images an authentication target irradiated with light of the self-luminous element layer via the first ¼ wavelength plate and the first polarizing plate, and may image light from the authentication target as a vein image via the first polarizing plate, the first ¼ wavelength plate, the self-luminous element layer, the second ¼ wavelength plate, and the second polarizing plate, and

the electronic device may further include:

a signal processing unit that extracts a feature point from the vein image;

a storage unit that stores a feature point of a vein of the authentication target; and

an authentication unit that collates the feature point extracted from the vein image with the feature point of the vein of the authentication target to determine whether or not the feature points coincide with each other.

The self-luminous element layer may be an organic light emitting diode.

The imaging device may include:

an on-chip lens; and

a metal light shielding film including a pinhole corresponding to a position in which the on-chip lens condenses light.

The imaging device may further include

a metal wire grid polarization element.

The metal wire grid polarization element

may be provided in the pinhole.

The imaging device may include a pixel array including a plurality of pixels, and

a pixel may include:

a plurality of subpixels each including a photoelectric conversion element that receives light incident at a predetermined angle and outputs an analog signal on the basis of intensity of the received light; and

an on-chip lens that condenses the incident light on a subpixel.

A polarization element may be formed in at least one of the subpixels.

The polarization element may be a wire grid polarizing element including metal. The wire grid polarization element may be a structure formed by stacking a light reflection layer including a first conductive material and a light absorption layer including a second conductive material on the reflection layer.

The imaging device may include a color filter in a pixel, and

a difference between a wavelength corresponding to a spectrum center of gravity of the color filter and a wavelength corresponding to an emission spectrum center of gravity of the self-luminous element layer at the time of authentication may be ±50 nm or smaller.

In the second polarizing plate, a reflection type polarizing filter and an absorption type polarizing filter may be stacked.

The second polarizing plate may include a wire grid polarization element, and

may be a structure formed by stacking a light reflection layer including a first conductive material and a light absorption layer including tungsten or a tungsten compound on the light reflection layer.

In a case where a film thickness of the second ¼ wavelength plate is set to T, a refractive index of a normal light beam is set to ne, and a refractive index of an abnormal light beam is set to no, a difference between 4×T×(ne−no), which is a target wavelength, and an emission spectrum center of gravity of the self-luminous element layer at the time of authentication may be 0.05 um or smaller.

In a case where light emission of the self-luminous element layer at the time of authentication is other than white, a thickness of the first ¼ wavelength plate is T1 [um], and a thickness of the second ¼ wavelength plate is T2 [um], the first and second ¼ wavelength plates may include the same material, and regularity in a case where T1 [um] is divided by 60 and regularity in a case where T2 [um] is divided by 60 may be different from each other.

In a case where authentication fails, the self-luminous element layer may emit light in an irradiation range further limited than the irradiation range at the time of the failed authentication according to a position in which a living body is placed.

The imaging device may include:

a light reception unit for each pixel;

a charge accumulation unit; and

a transistor that transfers a signal charge accumulated in the light reception unit to the charge accumulation unit.

In the imaging device, light shielding metal may be arranged on the charge accumulation unit, and the light shielding metal may have a pinhole shape on the light reception unit for each pixel.

In the imaging device, light shielding metal may be arranged on the charge accumulation unit, and the light shielding metal may form a wire grid type polarizer on the light reception unit for each pixel.

In the imaging device, light shielding metal may be arranged on the charge accumulation unit, and the light shielding metal may have a pinhole shape on the light reception unit for each pixel and form a wire grid type polarizer in the pinhole.

The imaging device may perform authentication by a flip operation in biometric authentication.

An authentication unit having a barcode reader function of authenticating a geometric shape on the basis of an image imaged by the imaging device may be further included.

The authentication unit may be capable of authenticating an imaging target that is moving relative to the imaging device.

### BRIEF DESCRIPTION OF DRAWINGS

FIG. 1A is a schematic cross-sectional view of an electronic device according to a first embodiment.

FIG. 1B is a schematic cross-sectional view illustrating an example of an electronic device 1 not including an optical system.

FIG. 2(a) is a schematic external view of the electronic device in FIG. 1, and FIG. 2(b) is a cross-sectional view taken along line A-A of FIG. 2(a).

FIG. 3 is a block diagram illustrating a configuration example of an imaging unit.

FIG. 4 is a view illustrating a cross-sectional structure in a case where a multi-stage lens of a pixel 100 illustrated in FIG. 3 is used.

FIG. 5 is a block diagram illustrating a configuration example by a subpixel of the imaging unit.

FIG. 6A is a diagram illustrating an example of a back-illuminated imaging element.

FIG. 6B is a diagram illustrating an example of a photoelectric conversion element separation unit.

FIG. 7 is a schematic perspective view of a wire grid polarization element including a wire grid.

FIG. 8 is a conceptual diagram for illustrating light and the like passing through the wire grid polarization element.

FIG. 9 is a schematic diagram of a configuration in a case where the imaging unit serves as a fingerprint sensor.

FIG. 10 is a diagram for illustrating an optical characteristic such as a polarization state in an optical path in detail.

FIG. 11 is a diagram for illustrating an optical characteristic such as a polarization state in an optical path in detail.

FIG. 12 is a schematic configuration example of the electronic device that is an example of an imaging device.

FIG. 13A is a block diagram of a signal processing unit.

FIG. 13B is a diagram illustrating a reflectance of a skin surface.

FIG. 14 is a flowchart illustrating a flow of processing of the electronic device 1.

FIG. 15 is a schematic cross-sectional view of the electronic device.

FIG. 16 is a plan view of a reflector.

FIG. 17 is a schematic diagram in a case where a polarizing plate is formed in the fingerprint sensor.

FIG. 18 is a diagram illustrating a cross-sectional structure of a pixel in a case where the polarizing plate is formed in the fingerprint sensor.

FIG. 19 is a diagram illustrating a configuration example of a polarizing plate according to a second embodiment.

FIG. 20 is a diagram illustrating an example of a circuit configuration of the pixel according to the second embodiment.

FIG. 21 is a schematic diagram in a case where a polarizing plate is formed in a pinhole of a first light shielding film.

FIG. 22 is a schematic diagram in a case where the polarizing plate is formed in a pixel.

FIG. 23 is a block diagram illustrating a schematic configuration example of an electronic device according to the second embodiment.

FIG. 24 is a schematic diagram in a case where a ¼ wavelength plate is further formed in the fingerprint sensor.

FIG. 25 is a diagram illustrating a cross-sectional structure of the pixel in a case where the ¼ wavelength plate is further formed in the fingerprint sensor.

FIG. 26 is a schematic diagram in a case where the ¼ wavelength plate and the polarizing plate are formed in a pinhole 50.

FIG. 27 is a schematic diagram in a case where the ¼ wavelength plate and the polarizing plate are formed in the pixel.

### MODE FOR CARRYING OUT THE INVENTION

Hereinafter, an embodiment of an electronic device is described with reference to the drawings. Although principal components of the electronic device are mainly described hereinafter, the electronic device may have components and functions that are not illustrated or described. The following description does not exclude components and functions that are not illustrated or described.

### First Embodiment

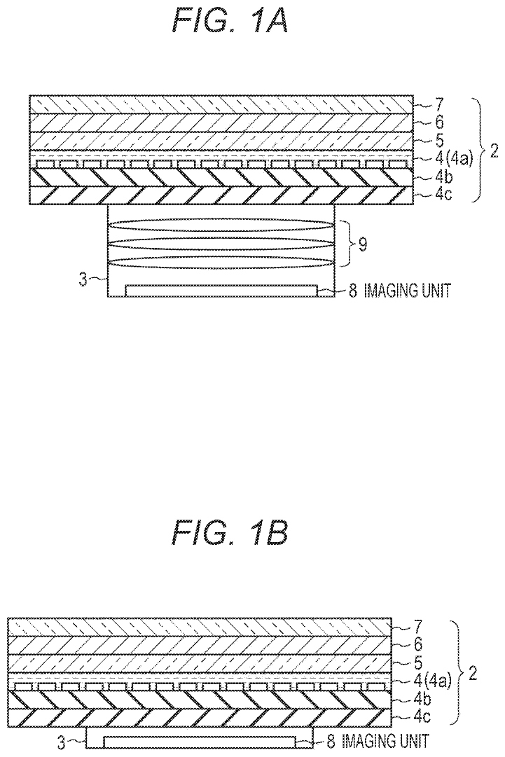

FIG. 1A is a schematic cross-sectional view of an electronic device 1 according to a first embodiment. The electronic device 1 in FIG. 1A as an example of the electronic device 1 including an optical system is any electronic device having both a display function and an imaging function such as a smartphone, a mobile phone, a tablet, a bar code reader, and a PC, and is provided with a module lens 9. In contrast, FIG. 1B is a schematic cross-sectional view illustrating an example of the electronic device 1 not including the module lens. The electronic device 1 in FIGS. 1A and 1B is provided with a camera module (imaging unit) arranged on a side opposite to a display surface of a display unit 2. In this manner, the electronic device 1 in FIG. 1 is provided with a camera module 3 on a back side of the display surface of the display unit 2. Therefore, the camera module 3 performs imaging via the display unit 2.

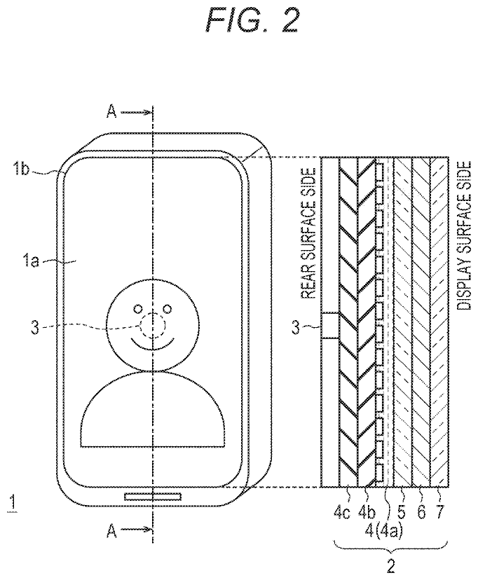

FIG. 2(a) is a schematic external view of the electronic device 1 in FIG. 1, and FIG. 2(b) is a cross-sectional view taken along line A-A of FIG. 2(a). In an example in FIG. 2(a), a display screen 1a extends nearly an outer shape size of the electronic device 1, and a width of a bezel 1b around the display screen 1a is set to several millimeters or smaller. In general, a front camera is often mounted on the bezel 1b, but in FIG. 2(a), as indicated by a broken line, the camera module 3 serving as the front camera is arranged on a back surface side of a substantially central portion of the display screen 1a. By providing the front camera on the back surface side of the display screen 1a in this manner, it becomes not necessary to arrange the front camera on the bezel 1b, and the width of the bezel 1b may be narrowed.

Note that, in FIG. 2(a), the camera module 3 is arranged on the back surface side of the substantially central portion of the display screen 1a, but in this embodiment, it is sufficient that this is arranged on the back surface side of the display screen 1a, and the camera module 3 may be arranged on the back surface side near a peripheral edge of the display screen 1a, for example. In this manner, the camera module 3 in this embodiment is arranged in any position on the back surface side overlapping the display screen 1a.

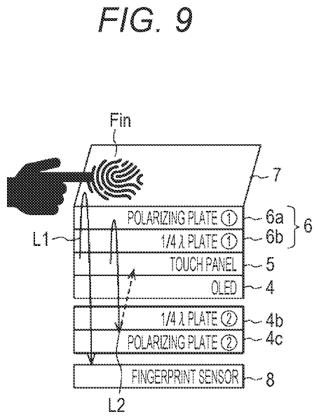

As illustrated in FIGS. 1A and 1B, the display unit 2 is a structure formed by stacking a polarizing plate 4c, a ¼ wavelength plate 4b, a display panel 4 (4a), a touch panel 5, a circularly polarizing plate 6, and a cover glass 7 (which may include a touch panel) in this order. Furthermore, the circularly polarizing plate 6 includes a polarizing plate 6a and a ¼ wavelength plate 6b (refer to FIG. 9) as described later.

The polarizing plate 4c and the ¼ wavelength plate 4b suppress incidence of internal reflected light on the camera module 3. The polarizing plate 4c and the ¼ wavelength plate 4b are described later in detail.

The display panel 4 may be, for example, an organic light emitting diode (organic light emitting device: OLED), a liquid crystal display unit, a MicroLED, or a display panel based on other display principles. The display panel 4 such as the OLED includes a plurality of layers. The display panel 4 is often provided with a member having low transmittance such as a color filter layer. A through hole may be formed on the member having a low transmittance in the display panel 4 according to a place in which the camera module 3 is arranged. If subject light passing through the through hole is incident on the camera module 3, an image quality of an image imaged by the camera module 3 may be improved.

The circularly polarizing plate 6 is provided in order to reduce glare and enhance visibility of the display screen 1a even in a bright environment. A touch sensor is incorporated in the touch panel 5. There are various types of touch sensors such as a capacitance type and a resistance film type, but any type may be used. Furthermore, the touch panel 5 and the display panel 4 may be integrated with each other. The cover glass 7 is provided so as to protect the display panel 4 and the like.

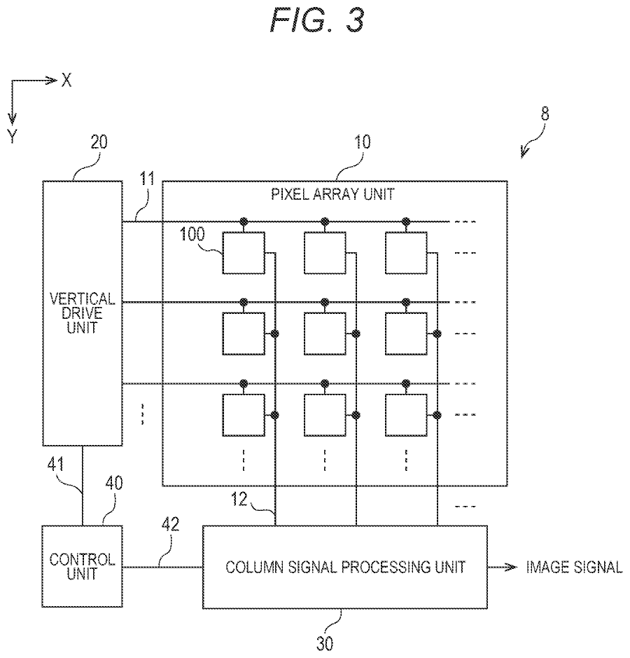

FIG. 3 is a block diagram illustrating a configuration example of an imaging unit 8. As illustrated in FIG. 3, the imaging unit 8 is provided with a pixel array unit 10, a vertical drive unit 20, a column signal processing unit 30, and a control unit 40.

The pixel array unit 10 includes a plurality of pixels 100. That is, the plurality of pixels 100 is arranged in a two-dimensional lattice pattern. The pixel 100 generates an image signal according to applied light. The pixel 100 includes a photoelectric conversion unit that generates a charge according to the applied light. Furthermore, the pixel 100 further includes a pixel circuit. The pixel circuit generates the image signal based on the charge generated by the photoelectric conversion unit. Generation of the image signal is controlled by a control signal generated by the vertical drive unit 20 to be described later. In the pixel array unit 10, signal lines 11 and 12 are arranged in an XY matrix pattern. The signal line 11, which is the signal line that transmits the control signal of the pixel circuit in the pixel 100, is arranged for each row of the pixel array unit 10 and is commonly wired to the pixels 100 arranged in each row. The signal line 12, which is the signal line that transmits the image signal generated by the pixel circuit of the pixel 100, is arranged for each column of the pixel array unit 10 and is commonly wired to the pixels 100 arranged in each column. The photoelectric conversion unit and the pixel circuit are formed in a semiconductor substrate.

The vertical drive unit 20 generates the control signal of the pixel circuit of the pixel 100. The vertical drive unit 20 transmits the generated control signal to the pixel 100 via the signal line 11 in the drawing.

The column signal processing unit 30 processes the image signal generated by the pixel 100. The column signal processing unit 30 processes the image signal transmitted from the pixel 100 via the signal line 12 in the drawing. The processing by the column signal processing unit 30 corresponds to, for example, analog-digital conversion to convert an analog image signal generated in the pixel 100 into a digital image signal. The image signal processed by the column signal processing unit 30 is output as the image signal of the imaging element 1. The control unit 40 controls an entire imaging unit 8. The control unit 40 generates the control signal that controls the vertical drive unit 20 and the column signal processing unit 30 to control the pixel (imaging element) 100. The control signal generated by the control unit 40 is transmitted to the vertical drive unit 20 and the column signal processing unit 30 via signal lines 41 and 42, respectively.

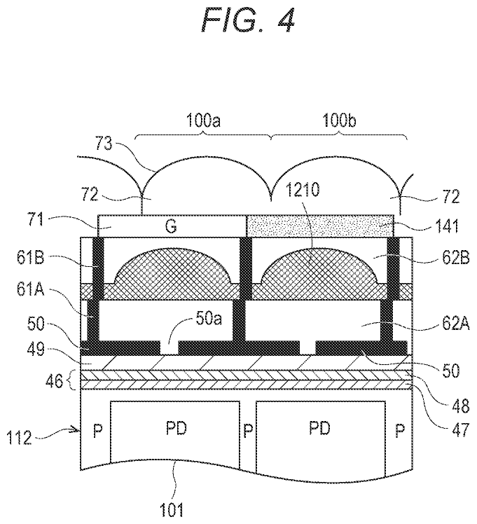

FIG. 4 is a diagram illustrating an example of a cross-sectional structure of the pixel 100 illustrated in FIG. 3. Pixels 100a and 100b represent an example of pixels arranged side by side in the pixel array unit 10. In the imaging unit 8, an n-type semiconductor region is formed in, for example, a p-type semiconductor region of a semiconductor substrate 112 for each of the pixels 100a and 100b. Therefore, a photoelectric conversion element PD is formed for each pixel. A multi-layer wiring layer including a transistor that reads charges accumulated in the photoelectric conversion element PD and the like and an interlayer insulating film is formed on a front surface side (lower side in the drawing) of the semiconductor substrate 112.

An insulating layer 46 including a negative fixed charge is formed on an interface on a back surface side (upper side in the drawing) of the semiconductor substrate 112. The insulating layer 46 includes films of a plurality of layers having different refractive indices, for example, two layers of a hafnium oxide (HfO2) film 48 and a tantalum oxide (Ta2O5) film 47, and the insulating layer 46 electrically suppresses a dark current by pinning enhancement and optically serves as an antireflection film.

A silicon oxide film 49 is formed on an upper surface of the insulating layer 46, and a first light shielding film 50 on which a pinhole 50a is formed is deposited on the silicon oxide film 49. The first light shielding film 50 only needs to include a material that shields light, and is preferably formed by using a film of metal, for example, aluminum (Al), tungsten (W), titanium (Ti), or copper (Cu) as a material having a strong light shielding property and capable of being accurately processed by microfabrication, for example, etching. Alternatively, this may be provided as an alloy thereof or a multi-layer film of these metals. The first light shielding film 50 on which the pinhole 50a is formed suppresses color mixture between the pixels and light of a flare component incident at an angle not supposed.

On the first light shielding film 50 and the insulating layer 46, a plurality of stages of layers of a light shielding wall 61 and flattening films 62A and 62B having high light transmittance is formed. More specifically, a first light shielding wall 61A is formed in a part on the first light shielding film 50 between the pixels, and a first flattening film 62A is formed between the first light shielding walls 61A. Moreover, a second light shielding wall 61B and the second flattening film 62B are formed on the first light shielding wall 61A and the first flattening film 62A, respectively. Note that, the light shielding wall herein may include a material of metal, for example, tungsten (W), titanium (Ti), aluminum (Al), or copper (Cu), or an alloy thereof, or a multi-layer film of these metals. Alternatively, this may include an organic light shielding material such as carbon black. Alternatively, a transparent inorganic film having a structure in which crosstalk is suppressed by a total reflection phenomenon due to a difference in refractive index may also be used, and for example, a shape in which an uppermost portion is closed as an air gap structure may also be used. In order to close the uppermost portion as the air gap structure, a depositing method with poor coverage, for example, sputtering and the like may be used.

On upper surfaces of the second light shielding wall 61B and the second flattening film 62B, for example, color filters 71 are formed for each pixel. As arrangement of the color filters 71, respective colors of red (R), green (G), and blue (B) are arranged by, for example, a Bayer arrangement, but they may be arranged by other arrangement methods. Alternatively, the imaging unit 8 may be formed without arranging the color filters 71.

An on-chip lens 72 is formed on the color filter 71 for each pixel. The on-chip lens 72 may include an organic material such as styrene resin, acrylic resin, styrene-acrylic copolymer resin, and siloxane resin, for example. The styrene resin has a refractive index of about 1.6, and the acrylic resin has a refractive index of about 1.5. The styrene-acrylic copolymer resin has a refractive index of about 1.5 to 1.6, and the siloxane resin has a refractive index of about 1.45. Alternatively, for example, an inorganic material such as SiN and SiON may also be used. SiN has a refractive index of about 1.9, and SiON has an intermediate refractive index between that of SiN and the silicon oxide film.

In addition to red, green, and blue, a filter layer that transmits a specific wavelength such as cyan, magenta, and yellow may be provided as the color filter 71. The color filter 71 may include not only an organic material-based color filter layer in which an organic compound such as pigment or dye is used, but also a thin film including an inorganic material such as a photonic crystal, a wavelength selecting element to which plasmon is applied (a color filter layer having a conductor lattice structure acquired by providing a lattice hole structure on a conductor thin film; for example, refer to JP 2008-177191 A), amorphous silicon and the like.

An inner lens 1210 includes, for example, an inorganic material such as SiN or SiON. The inner lens 1210 is formed on a formed first-stage light shielding wall layer (the first light shielding wall 61A and the first flattening film 62A). By providing the inner lens, it is possible to increase light condensing power and make a spot diameter of a beam waist small. Note that a plurality of stages of inner lens may be provided in one pixel, or the imaging unit 8 may be formed without including the inner lens. In a light condensing design of the pixel 100, a light condensing point desirably coincides with the pinhole 50a on the first light shielding film 50.

The structure illustrated in FIG. 4 is merely an example, and the pinhole 50a may be formed in a wiring layer of a front-illuminated imaging device, and the on-chip lens or the inner lens may be provided so that the light condensing point coincides with the pinhole, for example. Alternatively, the pinhole 50a may be formed using light shielding metal as a smear countermeasure of a charge coupled device (CCD), and the on-chip lens or the inner lens may be provided so that the light condensing point coincides with the pinhole.

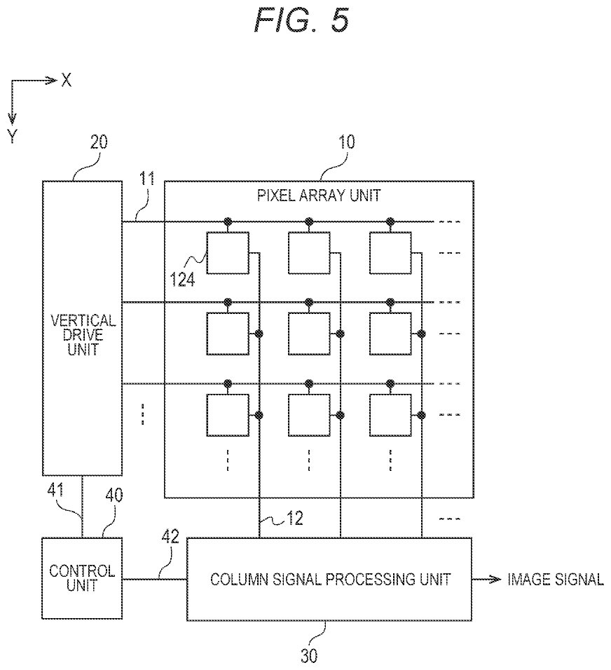

As another embodiment of the imaging device, a case where the pixel array unit 10 includes a subpixel 124 is described. A subpixel is defined as a concept indicating each divided region in a case where the on-chip lenses or the inner lenses are provided at the same period as that of the pixels, a light receiving element of one pixel is divided into a plurality of regions, and each of the regions is provided with the photoelectric conversion element. The subpixel may give parallax information in addition to intensity of received light. FIG. 5 is a block diagram illustrating a configuration example by the subpixel 124 of the imaging unit 8. As illustrated in FIG. 5, the imaging unit 8 is different from the imaging unit 8 illustrated in FIG. 3 in reading a signal from the subpixel 124. Since other configuration is equivalent to that of the imaging unit 8 illustrated in FIG. 3, the description thereof is omitted.

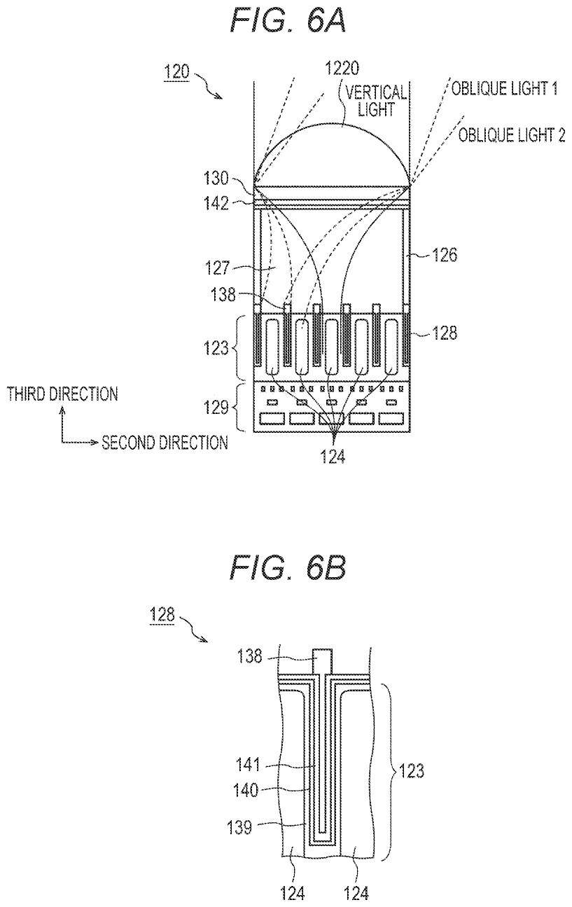

FIG. 6A is a diagram illustrating an example of a configuration of the subpixel 124. As illustrated in FIG. 6A, a pixel 120 is further provided with a semiconductor substrate 123, a plurality of subpixels 124, a plurality of photoelectric conversion element separation units 128 provided between the subpixels 124, a wiring layer 129 including an insulating layer and a wiring layer, a lens 1220, and a light shielding wall 126 between the pixels.

A plurality of subpixels 124 is provided for one pixel 120. For example, 5×5=25 subpixels 124 may be provided for one pixel 120. The subpixel 124 is, for example, a photodiode. The number of the subpixels 124 is not limited thereto, and may be more or less than 25 as long as processing may be appropriately executed. Furthermore, all the subpixels 124 are illustrated as the same squares, but they are not limited thereto, and may have appropriate shapes on the basis of information desired to be acquired according to various situations. Alternatively, a different filter may be used for each subpixel 124 provided on the pixel 100.

FIG. 6A is an example in a back-illuminated imaging element. As illustrated in FIG. 6A, illustrated is a case where a light beam (vertical light) parallel to installation of the element (parallel to an optical axis of the lens 1220) and a light beam (oblique light 1, 2) in an oblique direction (a direction not parallel to the optical axis of the lens 1220) are incident in a third direction. For example, a bundle of parallel light beams (solid line) incident from an upper portion of the lens 1220 is condensed to the subpixel 124 located on the center. In contrast, a bundle of light beams (dotted line) incident in the oblique direction is condensed to the subpixel 124 that is not on the center. Note that, in the description above, as an example, a vertical optical axis of the lens 1220 is used as a reference, but this is not necessarily the case, and it is also possible to determine the direction of the light beam incident on the subpixel 124 located on the center of the pixel 120 by a pupil correction technique and the like to be described later.

In the semiconductor substrate 123, for example, a silicon substrate, a semiconductor region portion of an element forming the pixel circuit is formed. The element of the pixel circuit is formed in a well region formed in the semiconductor substrate 123. For convenience, the semiconductor substrate 123 in the drawing includes a p-type well region.

The pixel 120 includes a plurality of photoelectric conversion elements 124, and the subpixel 124 includes an n-type semiconductor region and the p-type well region around the n-type semiconductor region. When incident light is applied to a pn junction between the n-type semiconductor region and the p-type well region, photoelectric conversion occurs. The charge generated by the photoelectric conversion is converted into the image signal by a pixel circuit not illustrated. Semiconductor region portions of the vertical drive unit, the column signal processing unit, and the control unit are further formed in the semiconductor substrate 123.

The wiring layer 129 connects the semiconductor elements in the pixel to each other. Furthermore, the wiring layer 129 is also used for connection to a circuit outside the pixel, and forms a signal line. A wire of the wiring layer 129 includes, for example, metal such as copper and aluminum to transmit an electric signal, and the insulating layer includes, for example, silicon oxide to insulate between the wires.

In a case of the back-illuminated imaging element, the insulating layer and the wire are formed adjacently on a front surface side of the semiconductor substrate 123 to form the wiring layer 129. Moreover, a support substrate not illustrated is arranged adjacently to the wiring layer 129. The support substrate is a substrate that supports the imaging element, and improves strength at the time of manufacturing the imaging element. A stacked type in which a logic circuit and the like is mounted on the support substrate in advance, and the semiconductor substrate 123 and the circuit of the support substrate are electrically connected to each other may also be used.

FIG. 6B is a diagram illustrating an example of the photoelectric conversion element separation unit 128. The photoelectric conversion element separation unit 128 may be provided with a p-type well region 139. Moreover, a groove may be formed in the semiconductor substrate 123 so as not to propagate the information regarding the intensity of light to the photoelectric conversion element of the adjacent subpixel (photoelectric conversion unit) 124, and an insulating film 141 may be provided in the groove. Moreover, a metal film 138 may be provided in addition to the insulating film 141. A film 140 having a negative fixed charge may be provided on a light receiving surface of the semiconductor substrate 123 and a trench sidewall of the photoelectric conversion element separation unit 128. Since pinning is enhanced in the fixed charge film 140 by an inversion layer generated on a contact surface in the semiconductor substrate, generation of a dark current is suppressed. The negative fixed charge film 140 may include, for example, an oxide or nitride including at least one of hafnium, zirconium, aluminum, tantalum, or titanium.

The insulating film 141 includes, for example, silicon oxide and the like, and insulates the photoelectric conversion element of the subpixel 124 from the metal film 138.

The metal film 138 includes an opening on at least a part of the subpixel 124, and may be further embedded in a clearance of the insulating film 141 in the trench of the photoelectric conversion element separation unit 128. The metal film 138 may shield a black reference pixel region and a peripheral circuit region from light by covering them. The metal film 138 may include a material having a light shielding property, for example, a metal film of tungsten, aluminum, silver, gold, copper, platinum, molybdenum, chromium, titanium, nickel, iron, tellurium and the like, a compound of these metals, an oxide of these metals, a nitride of these metals, or an alloy of these metals. Furthermore, these materials may be combined as a multi-layer film. Moreover, in consideration of a line width and a process variation of misalignment of the light shielding wall 126 and the metal film 138, a residual width of the metal film 138 on a boundary of the pixel 100 may be made thicker than the residual width of the metal film 138 other than the boundary of the pixel 100.

The residual width of the metal film 138 of the photoelectric conversion element separation unit 128 may be larger or smaller than a trench width formed in the semiconductor substrate 123. The former suppresses deterioration in dark current and white spot characteristic and improves angular resolution. The latter improves sensitivity. Moreover, in a part of the photoelectric conversion element separation unit 128 included in the pixel 100, it is possible that the metal film 138 is provided only in the clearance of the insulating film 141 in the trench, and the metal film 138 is not provided above a surface of the insulating film 141.

The interlayer film 127 is provided on the metal film 138, and may include a transparent material such as silicon oxide, silicon nitride, and SiON, for example. In a case where the light shielding wall 126 is not formed and the like, an organic material such as a styrene resin, an acrylic resin, a styrene-acrylic copolymer resin, and a siloxane resin may be used, and the lens 1220 may be directly provided on the organic material.

The light shielding wall 126 may be provided so as to penetrate the interlayer film 127 on a boundary of the pixel 120. By providing the light shielding wall 126, stray light may be shielded. The light shielding wall 126 may include a material having a light shielding property, for example, a metal film of tungsten, aluminum, silver, gold, copper, platinum, molybdenum, chromium, titanium, nickel, iron, tellurium and the like, a compound of these metals, an oxide of these metals, a nitride of these metals, or an alloy of these metals. Furthermore, a multi-layer film acquired by combining these materials may also be formed. Alternatively, this may include an organic light shielding material such as carbon black. Alternatively, a transparent inorganic film having a structure in which crosstalk is suppressed by a total reflection phenomenon due to a difference in refractive index may also be used, and for example, a shape in which an uppermost portion is closed as an air gap structure may also be used. Moreover, the light shielding wall 126 may be divided in multiple stages in the third direction. On the boundary of the pixel 100, the light shielding wall 126 and the metal film 138 may be continuously in contact with each other.

The color filter 130 may use, for example, pigment or dye as a material, transmit light of a desired wavelength, and acquire spectrum information of light from a subject. The color filter 130 may be provided, for example, on the interlayer film 127, and an adhesion layer 142 also for flattening may be provided between the interlayer film 127 and the color filter 130. The color filter 130 may be provided, for example, on the metal film 138, and an adhesion layer also serving as a flattening film may be provided between the metal film 138 and the color filter 130. One color filter 130 may be provided for one subpixel 124, for example, and they may be different for each subpixel 124. Alternatively, one color filter 130 may be provided for one pixel 100, and they may be different for each pixel 100. It is also possible that the color filter is not provided while putting an emphasis on sensitivity and resolution.

One lens 1220 is provided for one pixel 120, for example. Alternatively, the lens 1220 may include a plurality of stacked lenses. The lens may include an organic material such as a styrene resin, an acrylic resin, a styrene-acrylic copolymer resin, or a siloxane resin, for example. Furthermore, this may also include an inorganic material such as silicon nitride or silicon oxynitride. An antireflection film having a different refractive index may be provided on a lens surface. Moreover, for an underlying step, for example, a flattening film including an organic material, for example, an acrylic resin may be provided under the lens material. Alternatively, as another means, a transparent inorganic material flattened by CMP and the like, for example, silicon oxide may be provided.

The imaging device provided with the pinhole on the pixel or the imaging device provided with a plurality of subpixels in the pixel is heretofore described as an example, but it is not necessary to be as described above, and for example, this may be the front-illuminated type instead of the back-illuminated type. Alternatively, an organic photoelectric conversion film may be used in place of the photoelectric conversion element by the pn junction in the semiconductor substrate. Moreover, if a sufficient space may be secured in a case of using a module lens, it is possible to acquire a subject image with less blur even with a pixel not provided with the pinhole or the subpixel in the imaging device by a design of the module lens, and these combinations are not excluded.

Here, the ¼ wavelength plates 4b and 6b are described in detail. The ¼ wavelength plates 4b and 6b are wavelength plates that give a phase difference of 90 degrees (=λ/4) between two vertically polarized components of the incident light to emit. Furthermore, the ¼ wavelength plates 4c and 6b convert linearly polarized light into circularly polarized light. Furthermore, the ¼ wavelength plates 4b and 6b reversibly convert circularly polarized incident light into linearly polarized light to emit.

In further detail, the ¼ wavelength plates 4b and 6b function by shifting a phase between two vertically polarized components of a light wave. Typical ¼ wavelength plates 4b and 6b are birefringent crystals such as crystal and mica a direction of an optical axis and a film thickness T of which are determined. In a cut surface of the birefringent crystal, two axes, a normal axis having a refractive index of no and an abnormal axis having a refractive index of ne are acquired. The normal axis is perpendicular to the optical axis, and the abnormal axis is parallel to the optical axis. In a case of the light wave perpendicularly incident on a plate, a polarized component along the normal axis travels through the crystal at a velocity of vo=c/no, whereas a polarized component along the abnormal axis travels at a velocity of ve=c/ne. This results in a phase difference δ(λ) between the two components as they exit the crystal. That is, the phase difference δ(λ) may be expressed by expression (1).

[Expression 1]

δ(λ)=T×(ne−no)×(360/λ) (1)

Since the ¼ wavelength plate has the phase difference δ(λ) of 90 degrees, a wavelength λ may be expressed by expression (2). In this manner, there is a correspondence relationship expressed by expression (2) between the wavelength λ and the film thickness T of the ¼ wavelength plate.

[Expression 2]

λ=4×T×(ne−no) (2)

That is, the ¼ wavelength plates 4b and 6b according to this embodiment are set to have a thickness such that an optical path difference between the light transmitted through the normal axis and the light transmitted through the abnormal axis is set to a ¼ wavelength. More specifically, a light emission color is set in advance at the time of living body imaging, for example, fingerprint or vein imaging. For example, in a case where only a portion of the display panel 4a corresponding to green (G) is allowed to emit light, the thickness is set such that the wavelength λ corresponds to 550 nm.

In contrast, in a case where only a portion of the display panel 4a corresponding to green (G) and blue (B) is allowed to emit light, the thickness is set such that the wavelength λ corresponds to 500 nm. This makes it possible to perform the living body imaging with higher accuracy.

A difference between the wavelength λ expressed by expression (2) and the center of gravity of a light emission spectrum at a corresponding portion of the display panel 4a is made, for example, 0.05 um or smaller. Therefore, the phase difference δ(λ) generated by the ¼ wavelength plate may be made more closer to a design wavelength, and authentication accuracy is further improved.

Furthermore, the ¼ wavelength plates 4b and 6b may be mainly formed in three types of true zero order, multiple order, and compound zero order. The wavelength plate of the true zero order may be formed as a true zero order wavelength plate because a predetermined retardation (phase difference) is acquired in zeroth order at a design wavelength. This is formed by processing a sheet of birefringent material to be extremely thin so as to acquire a specific phase difference in zeroth order. For example, in a case where only a portion corresponding to the green filter (G) is allowed to emit light, a ¼ wavelength plate at 550 nm is manufactured. In this case, when the material is crystal, the phase difference corresponds to the thickness of 137.5 nm (=550 nm×¼). In order to acquire this phase difference with crystal (birefringence ne−no=0.0092), the crystal is processed to be thin up to about 15 μm (=137.5 nm/0.0092). Stability of the phase difference acquired with respect to a wavelength shift, a temperature change, or oblique incidence is superior to those of the multiple order or the compound zero order. In contrast, this thin plate might be damaged at the time of fixing to a device or handling, leading to a decrease in yield.

In a case of forming the ¼ wavelength plates 4b and 6b in the multiple order, they may be created by using the same one birefringent material as that of the true zero type. Furthermore, for the purpose of increasing the plate thickness to a practical level, it is possible to design so that a predetermined phase difference may be acquired at a high order. For example, in a case where only a portion corresponding to green (G) is allowed to emit light, in a case where a phase difference of 3.25 wavelengths is generated at a wavelength of 550 nm, the plate thickness may be increased up to about 194 μm in a case of crystal. The phase difference of 3.25 wavelengths is substantially equivalent to the phase difference of 0.25 wavelengths (=¼). However, as the plate thickness increases, a phase difference shift that cannot be ignored might occur also with a slight wavelength shift, temperature change and the like. In a case of the wavelength of 550 nm, a crystal thickness T1 may be expressed by expression (3). Note that, it is calculated supposing that 550/0.0092 is 60.0 μm. N represents the number of wavelengths. When N=0, this is the true zero order, and when N=1 or larger, this is the multiple order. Similarly, a crystal thickness T2 in a case of the wavelength of 500 nm may be calculated by expression (4). It is calculated supposing that 500/0.0092 is 54.3 μm.

[Expression 3]

T1=15.0+N×60.0 μm (3)

[Expression 4]

T2=12.5+N×54.3 μm (4)

In other words, in a case of the wavelength of 550 nm, N is acquired when subtracting 15 from T1 and multiplying the same by 0.0092/550. That is, N is acquired when subtracting 15 from T1 and dividing the same by 60. Similarly, in a case of the wavelength of 500 nm, N is acquired when subtracting 12.5 from T2 and multiplying the same by 0.0092/500. That is, N is acquired when subtracting 12.5 from T1 and dividing the same by 54.3. That is, when N is 0, this is the true zero order, and when N is a natural number, this is the multiple order. As described later, in a case of the compound zero order, N is a natural number and an even number.

Furthermore, when the thickness T1 is divided by 60, T1/60=0.25+N is acquired. In this case, if the thickness of the ¼ wavelength plate designed with the wavelength of λ2=500 nm is divided by 60, this is different from 0.25+N. Therefore, by dividing the film thickness T by λ1/(ne−no), it may be determined that the same wavelength is targeted when regularity is the same, for example, 0.25+N, and that a wavelength λ2 different from a wavelength λ1 is targeted when the regularity is different. Note that, in a case where N is 0, a division value is different.

In a case where the ¼ wavelength plates 4c and 6b are formed in the compound zero order (sometimes simply referred to as “zero order” for distinguishing from true zero order), it becomes possible to improve disadvantages of the above-described multiple order type. Optical axes of two birefringent materials of the same material manufactured in the multiple order are arranged so as to be orthogonal to each other. That is, this is a case where n is a natural number and an even number in expression (1) and (2). This makes it possible to decrease wavelength dependency and temperature dependency of the acquired retardation because a phase difference shift amount generated for each material cancel each other. However, it might be difficult to improve incident angle dependency.

In this manner, in a case where the wavelength of 550 nm is used, the thickness T1 of the ¼ wavelength plates 4b and 6b is set such that, when subtracting 15 from T1 and dividing the same by 60, 0 or a natural number is acquired. Similarly, in a case of the wavelength of 500 nm, the thickness T2 of the ¼ wavelength plates 4b and 6b is configured to be 0 or a natural number when subtracting 12.5 from T2 and dividing the same by 54.3. Therefore, according to the wavelength to be used, it is possible to set to the thickness with which the wavelength difference between the light transmitted through the normal axis and the light transmitted through the abnormal axis is ¼ wavelength, and imaging accuracy of the living body is further improved.

Here, the configuration of the polarizing plate 6a is described in detail. In the polarizing plate 6a, an absorption type polarizing filter, a reflection type polarizing filter, a crystal system, a multi-layer film system and the like may be used.

An absorption type polarization element 150 includes, for example, a film acquired by applying an appropriate treatment such as a dyeing treatment with a dichroic substance such as iodine and dichroic dye, a stretching treatment, or a crosslinking treatment in appropriate order and manner to a film of an appropriate vinyl alcohol-based polymer such as polyvinyl alcohol or partially formalized polyvinyl alcohol. In general, in the stretching treatment for producing a linear polarizer, a film is stretched in a longitudinal direction, so that, in the acquired linear polarizer, a polarization absorption axis parallel to the longitudinal direction of the linear polarizer and a polarization transmission axis parallel to a width direction of the linear polarizer are acquired. This linear polarizer is excellent in polarization degree. A thickness of the linear polarizer is generally, but not limited to, 5 μm to 80 μm.

A crystal system polarization element 150 may include, for example, a photonic crystal. The photonic crystal is a structure having periodicity of wavelength order of light in refractive index. By controlling the period and shape of the structure, the transmittance in the transmission axis and a reflectance in the absorption axis may be set. A multi-layer film system polarization element 150 includes, for example, a multi-layer film including at least two or more types of film materials having different refractive indices.

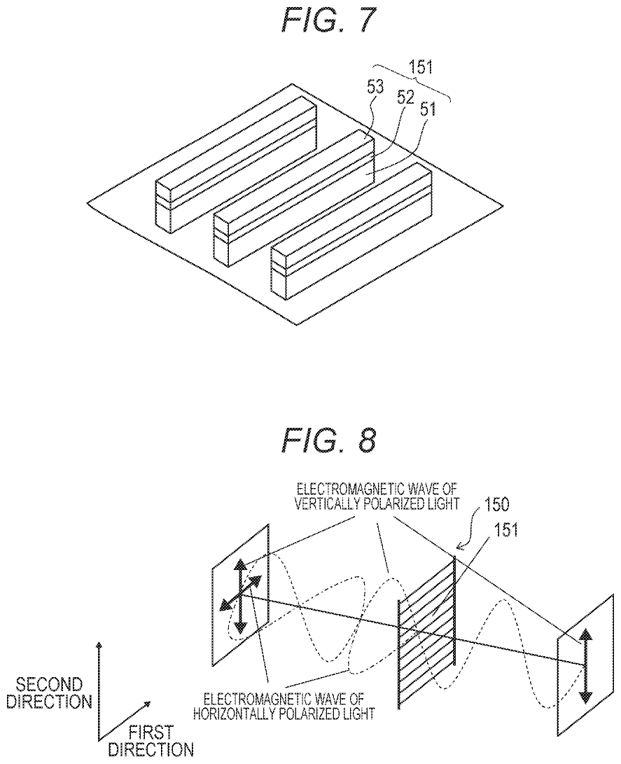

FIG. 7 is a schematic perspective view of a so-called reflection type wire grid polarization element 150 including a wire grid. The polarization element 150 in the drawing illustrates an example of the polarization element including the wire grid. The wire grid polarization element 150 is a polarization unit formed by arranging strip-shaped conductors 151 at a predetermined pitch. In the metal film having a wire grid shape, polarized light in an orientation in which free electrons in metal follow (longitudinal direction) is canceled by a reflected wave, and polarized light in an orientation in which the free electrons do not follow (lateral direction) is transmitted. The pitch of the wire grid polarization elements is preferably smaller than ½ of a used wavelength, and in a case where the pitch exceeds this, diffracted light is generated. The strip-shaped conductor 151 may be provided with a single layer of light reflection layer 51, or may be provided with a light absorption layer 53 stacked on the light reflection layer 51. Alternatively, an insulating layer 52 may be provided between the light reflection layer 51 and the light absorption layer 53. A component of the light reflection layer 51 is not especially limited as long as this is a material having reflectivity to light in a used band, and examples thereof include, for example, a simple substance of an element such as Al, Pt, Ag, Cu, Mo, Cr, Ti, Ni, W, Fe, Si, Ge, and Te, or an alloy including one or more of these elements. Among them, in a case where the polarizing plate is used for visible light application, the reflection layer preferably includes aluminum or an aluminum alloy. Alternatively, silver (Ag), copper (Cu), gold (Au) and the like is preferably used in order to impart a polarization characteristic to a wavelength band other than visible light, for example, an infrared region. This is because resonance wavelengths of these metals are in the vicinity of the infrared region. Note that, in addition to these metal materials, for example, an inorganic film or a resin film other than the metal formed with a high surface reflectance by coloring and the like may be used.

There is concern that reflected light by the wire grid polarization element 150 might become flare due to scattering in a housing and cause deterioration in image quality of the imaging device, or might give a feeling of strangeness in appearance due to a difference in reflectance from that of a peripheral member when strong light such as the sun is reflected on the display. As a reflected light control means, the light absorption layer 53 may be provided on the light reflection layer 51. Examples of the material forming the light absorption layer 53 may include a metal material, an alloy material, and a semiconductor material having an extinction coefficient k of not 0, that is, having a light absorbing action, specifically, metal materials such as tungsten (W), silver (Ag), gold (Au), copper (Cu), molybdenum (Mo), chromium (Cr), titanium (Ti), nickel (Ni), iron (Fe), silicon (Si), germanium (Ge), tellurium (Te), and tin (Sn), alloy materials including these metals, and semiconductor materials. Furthermore, silicide-based materials such as FeSi2 (especially β-FeSi2), MgSi2, NiSi2, BaSi2, CrSi2, and CoSi2 may also be exemplified. The light reflection layer 51 and the light absorption layer 53 may be formed on the basis of a known method such as various chemical vapor deposition methods (CVD methods), coating methods, various physical vapor deposition methods (PVD methods) including a sputtering method and a vacuum vapor deposition method, a sol-gel method, a plating method, an MOCVD method, and an MBE method.

As a material forming the insulating layer 52, an insulating material transparent to the incident light not having a light absorption characteristic may be used. For example, SiOX-based materials (materials forming a silicon-based oxide film) such as SiO2, non-doped silicate glass (NSG), boron-phosphorus silicate glass (BPSG), PSG, BSG, PbSG, AsSG, SbSG, and spin on glass (SOG), SiN, SiON, SiOC, SiOF, SiCN, low-dielectric-constant insulating materials (for example, fluorocarbon, cycloperfluorocarbon polymer, benzocyclobutene, cyclic fluororesin, polytetrafluoroethylene, amorphous tetrafluoroethylene, polyaryl ether, fluorinated aryl ether, fluorinated polyimide, organic SOG, parylene, fluorinated fullerene, amorphous carbon), polyimide resin, fluorine resin, Silk (trademark of The Dow Chemical Co.; a coating-type low-dielectric-constant interlayer insulating film material), and Flare (trademark of Honeywell Electronic Materials Co.; polyarylether (PAE)-based material) may be used. Furthermore, they may be used alone or in combination as appropriate. The insulating layer 52 may be formed on the basis of known methods such as various CVD methods, coating method, various PVD methods including a sputtering method and a vacuum vapor deposition method, various printing methods such as a screen printing method, and a sol-gel method. The insulating layer 52 is formed for the purpose of serving as an underlayer of the light absorption layer, and adjusting phases of polarized light reflected by the light absorption layer and polarized light transmitted through the light absorption layer and reflected by the light reflection layer to reduce the reflectance by an interference effect. Therefore, the insulating layer 52 preferably has such a thickness that the phase in one reciprocation is shifted by half a wavelength. However, since the light absorption layer 53 has a light absorbing effect, the reflected light is absorbed. Therefore, even if the thickness of the insulating layer 52 is not optimized as described above, improvement in extinction ratio may be achieved. Therefore, practically, it is sufficient to determine the thickness of the insulating layer on the basis of a balance between a desired polarization characteristic and an actual manufacturing step, and for example, 1×10−9 m to 1×10−7 m, and more preferably 1×10−8 m to 8×10−8 m may be exemplified. Furthermore, the refractive index of the insulating layer is larger than 1.0, and is preferably 2.5 or smaller without limitation.

Examples of a patterning method of the strip-shaped conductor 151 may include a combination of a lithography technique and an etching technique (for example, an anisotropic dry etching technique using carbon tetrafluoride gas, sulfur hexafluoride gas, trifluoromethane gas, xenon difluoride gas and the like, and a physical etching technique), a so-called lift-off technique, and a so-called self-aligned double patterning technique using a sidewall as a mask. Furthermore, as a lithography technique, a photolithography technique (lithography technique using a g-ray and an i-ray of a high-pressure mercury lamp, a KrF excimer laser, an ArF excimer laser, EUV and the like as a light source, and an immersion lithography technique, electron beam lithography technique, and X-ray lithography thereof) may be exemplified. Alternatively, the strip-shaped conductor 151 may be formed on the basis of a microfabrication technique using an ultra-short time pulse laser such as a femtosecond laser and a nanoimprint method.

In general, the refractive index between the wire grids is preferably lower for the polarization characteristic such as the extinction ratio, and an air layer is ideal; however, there is concern that the metal grid is deteriorated in a high-temperature environment in the air layer, and the polarization characteristic is deteriorated. As a countermeasure, a dielectric layer or both the dielectric layer and the air layer might be provided between the wire grids. A material forming the dielectric layer is not especially limited, but examples thereof include Si oxide such as SiO2, AlF2, BaF2, CeF3, LaF3, LiF, MgF2, NdF3, NaF, and YF3, for example, from the viewpoint of suppressing unnecessary reflection and the like of light beams to be polarized on the polarizing plate.

FIG. 8 is a conceptual diagram for illustrating light and the like passing through the wire grid polarization element. A direction in which the strip-shaped conductor 151 extends (a first direction) coincides with the absorption axis to quench, and a repeating direction of the strip-shaped conductor 151 (a second direction orthogonal to the first direction) coincides with the transmission axis to transmit. That is, free electrons in the strip-shaped conductor 151 vibrate following an electric field of light incident on the strip-shaped conductor 151, and radiate the reflected wave. The incident light in a direction perpendicular to the direction in which the plurality of strip-shaped conductors 151 is arranged, that is, parallel to the longitudinal direction of the strip-shaped conductor (second direction) radiates more reflected light because the amplitude of free electrons becomes large. Therefore, the incident light in the first direction is reflected without being transmitted through the polarization element 150. In contrast, in light perpendicular to the longitudinal direction of the strip-shaped conductor (second direction), radiation of the reflected light from the strip-shaped conductor is reduced. This is because the vibration of the free electrons is limited and the amplitude is reduced. The incident light in the transmission axis (second direction) in which attenuation by the polarization element 150 is reduced may be transmitted through the polarization element 150. Note that, in a case where aluminum (Al) is used as the light reflection layer, the reflectance with respect to the incident light changes depending on an optical thickness of the light reflection layer 51 (refractive index×film thickness of the light reflection layer). Furthermore, the reflectance with respect to the incident light also changes depending on the optical thickness of the light absorption layer 53 (absorption rate×film thickness of the light reflection layer).

FIG. 9 is a schematic diagram of a configuration in a case where the imaging unit 8 serves as the fingerprint sensor. As illustrated in FIG. 9, the fingerprint is irradiated with light applied from the display panel (OLED) 4a along the optical path L1, and is imaged by the fingerprint sensor 8. That is, the finger is irradiated with the light applied from the OLED 4a (display panel 4) via the touch panel 5, the ¼ wavelength plate 6b, the polarizing plate 6a, and the cover glass 7, and scattered light from the finger is imaged by the fingerprint sensor 8 via the cover glass 7, the polarizing plate 6a, the ¼ wavelength plate 6b, the touch panel 5, the OLED 4a, the ¼ wavelength plate 4b, and the polarizing plate 4c. In contrast, a part of the light applied from the OLED 4a is reflected by the polarizing plate 6a along the optical path L2, further applied to the polarizing plate 4c via the ¼ wavelength plate 6b, the touch panel 5, the OLED 4a, and the ¼ wavelength plate 4b, and reflected by the polarizing plate 4c. In this embodiment, by further providing the ¼ wavelength plate 4b and the polarizing plate 4c, incidence of the noise component reflected along the optical path L2 on the fingerprint sensor 8 is suppressed.

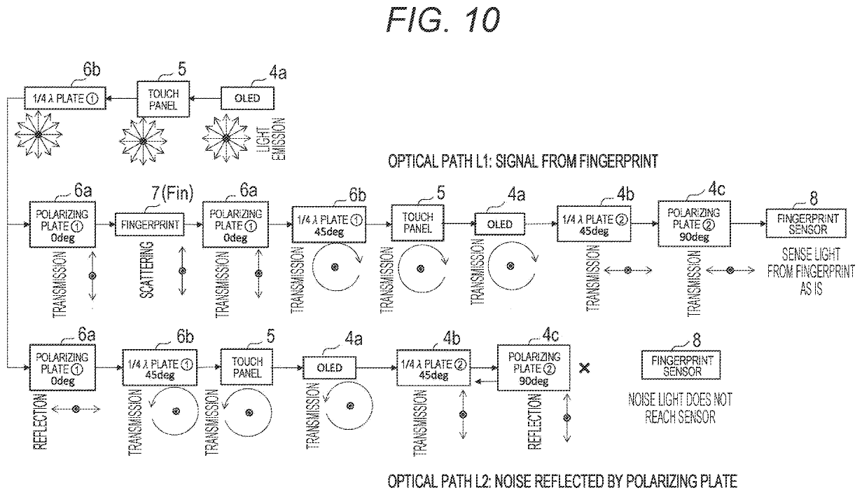

FIG. 10 is a diagram for illustrating an optical characteristic such as a polarization state in the optical paths L1 and L2 in detail. In the present invention, the absorption axis of the polarizing plate (1) may be optionally provided, and the optical axis of other optical members in FIG. 10 is defined relative to the polarizing plate (1). Here, for convenience, it is described while setting the transmission axis of the polarizing plate (1) to 0 degrees, and defining a sign of an angle such that a clockwise direction is a +direction with respect to a traveling direction of light.

An arrow on a lower side in FIG. 10 schematically indicates the transmission axis. The polarized light in the transmission axis of the polarizing plate (1), that is, at 0 degrees is indicated by a vertical arrow, and the polarized light orthogonal to the polarizing plate (1) is indicated by a horizontal arrow. In a case of circularly polarized light in FIG. 10, the traveling direction of the light is unified to a forward direction of the paper surface, and a rotation direction of the polarized light is indicated by an arc arrow. In a case of non-polarized light, a plurality of arrows in different polarization orientations is overwritten. A fingerprint Fin is irradiated with the light emitted from the OLED 4a via the touch panel 5, the ¼ wavelength plate 6b, the polarizing plate 6a, and the cover glass 7. The slow axis of the ¼ wavelength plate 6b is set to 45° (or 135°).

In the polarizing plate 6a, since the transmission axis is 0 degrees, light in the polarization orientation of 0 degrees is transmitted. The light scattered by the fingerprint Fin is transmitted through the ¼ wavelength plate 6b again as scattered light in the polarization orientation of 0 degrees. Since the traveling direction of the light is inverted, the slow axis of the ¼ wavelength plate 6b becomes 135° (or 45°), and the light in the polarization orientation of 0 degrees is transmitted as circularly polarized light rotating rightward (or rotating leftward). The light transmitted through the ¼ wavelength plate 6b is further transmitted through the touch panel 5 and the OLED 4a, and is incident on the ¼ wavelength plate 4b. The slow axis of the ¼ wavelength plate 4b is provided so as to coincide with that of 6b. In consideration of the traveling direction of light, this is 135° (or 45°), so that the ¼ wavelength plate 4b polarizes the incident light into linearly polarized light in the polarization orientation of 90 degrees. The polarizing plate 4c is provided so that the absorption axis is orthogonal to that of the polarizing plate 6a. Then, the linearly polarized light at 90 degrees transmitted through the ¼ wavelength plate 4b is transmitted through the polarizing plate 4c having the polarization orientation of 90 degrees, and is imaged by the fingerprint sensor 8.

In contrast, noise light in the optical path L2 reflected by the polarizing plate 6a is transmitted through the ¼ wavelength plate 6b as polarized light in a 90 degree direction. As described above, the slow axis of the ¼ wavelength plate 6b is 135° (or 45°), so that the light in the polarization orientation of 90 degrees is transmitted as circularly polarized light rotating leftward (or rotating rightward). The light transmitted through the ¼ wavelength plate 6b is further transmitted through the touch panel 5 and the OLED 4a, and is incident on the ¼ wavelength plate 4b. In consideration of the traveling direction of the light, the slow axis of the ¼ wavelength plate 4b is 135° (or 45°), so that circularly polarized light rotating leftward (or rotating rightward) is transmitted as linearly polarized light at 0 degrees. The linearly polarized light at 0 degrees transmitted through the ¼ wavelength plate 4b is reflected by the polarizing plate 4c having the polarization orientation of 90 degrees, and is not imaged by the fingerprint sensor 8.

In this manner, the signal component from the fingerprint of the optical path L1 reaches the fingerprint sensor 8 and is imaged. In contrast, the noise light in the optical path L2 reflected by the polarizing plate 6a is reflected by the polarizing plate 4c and cannot reach the fingerprint sensor 8. Therefore, the signal component from the fingerprint may be imaged in a state in which the noise component is reduced.

More specifically, a certain commercially available wire grid type polarizing plate has a reflectance of, for example, 50.6 percent for non-polarized vertical incidence, a transmittance of, for example, 45.3 percent, and a polarization degree of transmitted light of 99.1 percent. In a case where this wire grid type polarizing plate is applied to the polarizing plate 6a of this embodiment, the signal from the fingerprint is transmitted through the polarizing plate 6a twice while the light reaches the finger and escapes to the sensor side, so that the transmittance is approximately 0.453×(0.453/0.5)=41.0%. In contrast, a reflection component of the optical path L2 is 50.6 percent. Therefore, in a case where the ¼ wavelength plate 4b and the polarizing plate 4c are not provided, the noise component due to reflection by the polarizing plate 6a is 50.6 percent with respect to the signal from the fingerprint of 41.0 percent, that is, the influence of the noise becomes large at an SN ratio of −1.8 dB. Therefore, identification accuracy decreases.

In the example of the wire grid type polarizing plate 6a described above, in a case of further providing the ¼ wavelength plate 4b and the polarizing plate 4c of this embodiment and using the wire grid type polarizing plate described above as the polarizing plate 4c, the signal from the fingerprint is approximately 0.453×(0.453/0.5)×(0.453/0.5)=37.2%. In contrast, the noise light reflected by the polarizing plate 6a in the optical path L2 is approximately 0.516×0.453×(1−0.991)=0.2 percent in consideration of the transmittance and the polarization degree of the polarizing plate 4c, that is, an excellent SN ratio of 44.9 dB is acquired.

Furthermore, a certain commercially available absorption type polarizing plate (for example, a dichroic dye polarizer) has a reflectance of, for example, 5.1 percent for non-polarized vertical incidence, a transmittance of, for example, 18.5 percent, and a polarization degree of transmitted light of 99.1 percent. In a case where this absorption type polarizing plate is applied to the polarizing plate 6a of this embodiment, the signal from the fingerprint is transmitted through the polarizing plate 6a twice while the light reaches the finger and escapes to the sensor side, so that the transmittance is approximately 0.185×(0.185/0.5)=6.8%. In contrast, the reflection component of the optical path L2 is 5.1 percent. Therefore, in a case where the absorption type polarizing plate (dichroic dye polarizer) is used as the polarizing plate 6a, in a case where the ¼ wavelength plate 4b and the polarizing plate 4c are not provided, the noise component due to reflection by the polarizing plate 6a is 5.1 percent with respect to the signal from the fingerprint of 6.8 percent, that is, the influence of the noise becomes large at an SN ratio of 2.5 dB. Therefore, identification accuracy decreases.

In the example of the polarizing plate 6a of the absorption type polarizing plate described above, in a case of further providing the ¼ wavelength plate 4b and the polarizing plate 4c of this embodiment and using the absorption polarizing plate described above as the polarizing plate 4c, the signal from the fingerprint is 0.183×(0.183/0.5)×(0.183/0.5)=2.5%. In contrast, the noise light reflected by the polarizing plate 6a in the optical path L2 is 0.051×0.183×(1−0.991)=0.008 percent in consideration of the transmittance and the polarization degree of the polarizing plate 4c. That is, the SN ratio is 49.9 dB, and an excellent SN is acquired.

Note that these embodiments are examples used to quantitatively show the estimation of the acquired effect, and for example, one of the polarizing plates 6a and 4c may be the absorption type and the other may be the wire grid type, and the combination is not limited.

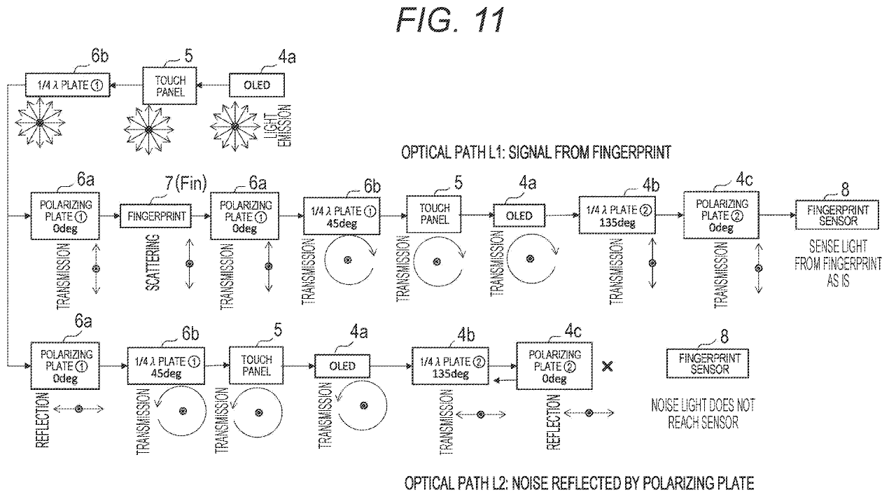

FIG. 11 is a diagram for illustrating the optical characteristic such as the polarization state in the optical paths L1 and L2 in detail, and is different from FIG. 10 in that the slow axes of the ¼ wavelength plates 6b and 4b are provided so as to be orthogonal to each other, and the absorption axes of the polarizing plates 6a and 4c are provided so as to coincide with each other.

As illustrated in FIG. 11, the polarized components of the light emitted by the OLED 4a are uniformly distributed in each direction. A fingerprint Fin is irradiated with the light emitted from the OLED 4a via the touch panel 5, the ¼ wavelength plate 6b, the polarizing plate 6a, and the cover glass 7. The slow axis of the ¼ wavelength plate 6b is set to 45° (or 135°).

In the polarizing plate 6a, since the polarization orientation is 0 degrees, light in the polarization orientation of 0 degrees is transmitted. The light scattered by the fingerprint Fin is transmitted through the ¼ wavelength plate 6b again as scattered light in the polarization orientation of 0 degrees. Since the traveling direction of the light is inverted, the slow axis of the ¼ wavelength plate 6b becomes 135° (or 45°), and the light in the polarization orientation of 0 degrees is transmitted as circularly polarized light rotating rightward (or rotating leftward). The light transmitted through the ¼ wavelength plate 6b is further transmitted through the touch panel 5 and the OLED 4a, and is incident on the ¼ wavelength plate 4b. As described above, the slow axis of the ¼ wavelength plate 4b is provided so as to be orthogonal. In consideration of the traveling direction of light, this is 135° (or 45°), so that the ¼ wavelength plate 4b polarizes the incident light into linearly polarized light in the polarization orientation of 0 degrees. The polarizing plate 4c is provided so that the absorption axis coincides with that of the polarizing plate 6a. Then, the linearly polarized light at 0 degrees transmitted through the ¼ wavelength plate 4b is transmitted through the polarizing plate 4c having the polarization orientation of 0 degrees, and is imaged by the fingerprint sensor 8.

In contrast, noise light in the optical path L2 reflected by the polarizing plate 6a is transmitted through the ¼ wavelength plate 6b as polarized light in a 90 degree direction. As described above, the slow axis of the ¼ wavelength plate 6b is 135° (or 45°), so that the light in the polarization orientation of 90 degrees is transmitted as circularly polarized light rotating leftward (or rotating rightward). The light transmitted through the ¼ wavelength plate 6b is further transmitted through the touch panel 5 and the OLED 4a, and is incident on the ¼ wavelength plate 4b. In consideration of the traveling direction of the light, the slow axis of the ¼ wavelength plate 4b is 45° (or 135°), so that circularly polarized light rotating leftward (or rotating rightward) is transmitted as linearly polarized light at 90 degrees. The linearly polarized light at 90 degrees transmitted through the ¼ wavelength plate 4b is reflected by the polarizing plate 4c having the polarization orientation of 0 degrees, and is not imaged by the fingerprint sensor 8.

In this manner, the signal component from the fingerprint of the optical path L1 reaches the fingerprint sensor 8 and is imaged. In contrast, the noise light in the optical path L2 reflected by the polarizing plate 6a is reflected by the polarizing plate 4c and cannot reach the fingerprint sensor 8. Therefore, the signal component from the fingerprint may be imaged in a state in which the noise component is reduced.

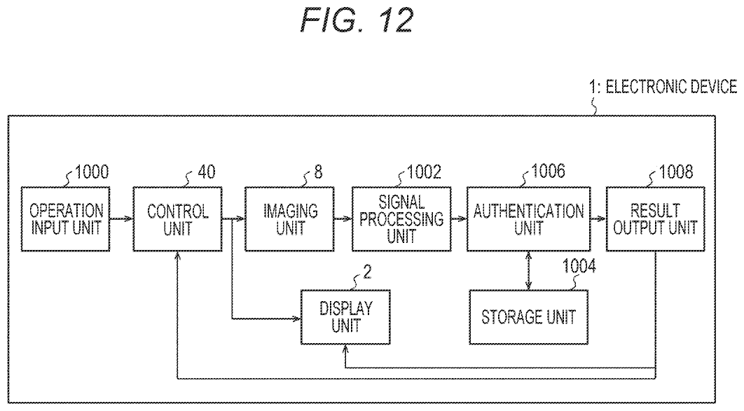

FIG. 12 is a block diagram illustrating a schematic configuration example of the electronic device 1, which is an example of the imaging device to which the present technology is applicable. The electronic device 1 is provided with the display unit 2 (FIGS. 1A and 1B), the imaging unit 8 (FIGS. 1A and 1B), the control unit 40 (FIG. 3), an operation input unit 1000, a signal processing unit 1002, a storage unit 1004, an authentication unit 1006, and a result output unit 1008.

The operation input unit 1000 receives an operation input from a user of the electronic device 1. The operation input unit 1000 includes, for example, a push button or a touch panel. The operation input received by the operation input unit 1000 is transmitted to the control unit 40 and the signal processing unit 1002. Thereafter, processing according to the operation input, for example, processing such as imaging of the fingerprint is activated.

As described above, the control unit 40 may transmit a command to the imaging unit to control the pixel array unit 10 (FIG. 3), and also transmit a command to the display unit 2 to illuminate a subject using a light source of the display unit 2. In illumination light, a balance of elements having different spectra of the display unit, for example, three primary colors of red, blue, and green may be changed, or a light emission area may be changed. Alternatively, a light source not illustrated different from that of the display unit 2 may be provided, and for example, light in an infrared region not included in organic EL may be emitted. Infrared radiation is suitable for acquiring information of the vein. Moreover, in a case where the electronic device 1 is provided with an optical system 9 (FIG. 1A), autofocus may be performed. Here, the autofocus is a system that detects a focal position of the optical system 9 to automatically adjust. As the autofocus, a method of detecting the focal position by detecting an image plane phase difference by a phase difference pixel arranged in the imaging unit 8 (image plane phase difference autofocus) may be used, for example. Furthermore, a method of detecting a position in which contrast of an image is the highest as the focal position (contrast autofocus) may also be applied. The control unit 40 adjusts a position of a lens of the optical system 9 via a lens drive unit (not illustrated) on the basis of the detected focal position and performs the autofocus. Note that, the control unit 40 may include, for example, a digital signal processor (DSP) equipped with firmware.

The signal processing unit 1002 processes an image signal generated by the imaging unit 8. This processing includes, for example, demosaicing of generating an image signal of a lacking color among the image signals corresponding to red, green, and blue for each pixel, noise reduction of removing noise of the image signal, processing of adding a plurality of pixels, encoding of the image signal and the like. The signal processing unit 1002 may include, for example, a microcomputer equipped with firmware.

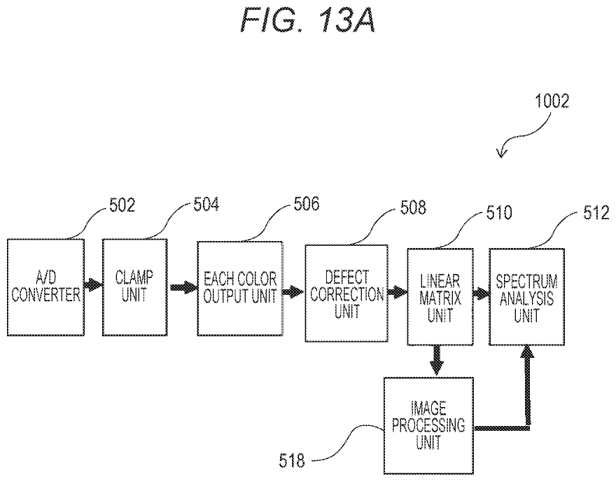

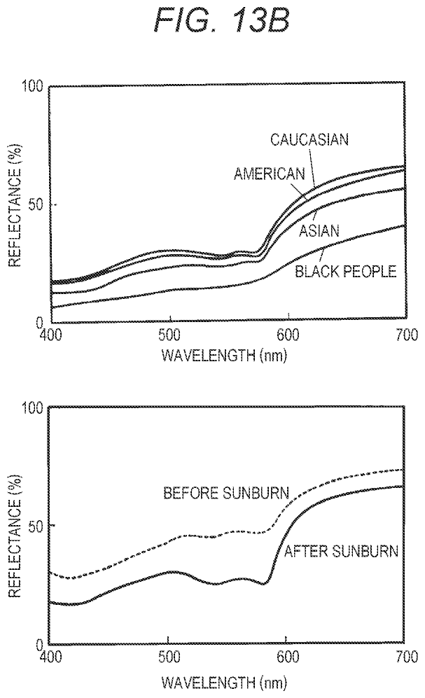

FIG. 13A is a block diagram of the signal processing unit 1002 according to this embodiment. As illustrated in FIG. 13A, the signal processing unit 1002 is provided with an A/D converter 502, a clamp unit 504, an each color output unit 506, a defect correction unit 508, a linear matrix unit 510, a spectrum analysis unit 512, and an image processing unit 518.

The analog to digital (A/D) converter 502 converts an analog signal output from the imaging unit 8 into a digital signal for each pixel.

The clamp unit 504 executes, for example, processing regarding a level of a ground in the image. For example, the clamp unit 504 defines a black level, subtracts the defined black level from image data output from the A/D converter 502 to output. The clamp unit 504 may set the ground level for each photoelectric conversion element provided in the pixel, and in this case, ground correction of a signal value may be performed for each acquired photoelectric conversion element.

For example, in a case where the analog signal is acquired for each color in the imaging unit 8, the each color output unit 506 outputs the image data output from the clamp unit 504 for each color. For example, in the imaging unit 8, red (R), green (G), and blue (B) filters are provided in the pixels. The clamp unit 504 adjusts the ground level on the basis of these filters, and the each color output unit 506 outputs the signal output by the clamp unit 504 for each color.

Since color data is not included in the analog signal acquired by the imaging unit 8, for example, the each color output unit 506 may store data of the filter provided for each pixel in the imaging unit 8 and output for each color on the basis of the data. Although it is assumed that the imaging unit 8 is provided with the color filter, there is no limitation, and for example, a color may be discriminated by an organic photoelectric conversion film.

The defect correction unit 508 executes correction of a defect in the image data. The defect of the image data occurs, for example, due to a lack of pixel or a lack of information due to a defect of the photoelectric conversion element provided in the pixel, or due to information missing and the like due to light saturation in the optical system 9. For example, the defect correction unit 508 may execute defect correction processing by performing interpolation processing on the basis of information of surrounding pixels or received intensity of surrounding photoelectric conversion elements in the pixel.

The linear matrix unit 510 performs correct color reproduction by executing matrix operation on color information such as RGB. The linear matrix unit 510 is also referred to as a color matrix unit. For example, the linear matrix unit 510 acquires a desired spectrum by performing an operation regarding a plurality of wavelengths. In this embodiment, for example, the linear matrix unit 510 performs an operation so as to perform an output suitable for detecting a skin color. The linear matrix unit 510 may be provided with an operation path of a different system from the skin color, and may perform an operation so as to acquire information of the vein, for example. Especially, in a case of acquiring the information of the vein, an operation may be performed so as to perform an output suitable for around 760 nanometers. The vein is rich in reduced hemoglobin, which has a characteristic absorption spectrum around 760 nanometers.

FIG. 13B is a diagram illustrating a reflectance of a skin surface. The reflectance is plotted along the ordinate and the wavelength is plotted along the abscissa. As illustrated in FIG. 13B, the skin color varies from individual to individual, but generally there is a rise in a wavelength region of 550 to 600 nanometers.

On the basis of the data output from the linear matrix unit 510, the spectrum analysis unit 512 determines, for example, whether or not there is a rise of a spectrum unique to the skin. The spectrum analysis unit 512 detects, for example, a rise of a signal of 550 to 600 nanometers in a range including 500 to 650 nanometers, thereby detecting whether a human finger is in contact with the cover glass 7, and in that case, detects the wavelength thereof, and outputs the same. The range to be determined is not limited to the above-described range, and may be wider or narrower than the above-described range in an appropriate range. For example, it is possible to analyze whether or not there is a peak around 760 nanometers of reduced hemoglobin.

The image processing unit 518 extracts a feature point of a fingerprint shape on the basis of the image signal generated by the linear matrix unit 510. Furthermore, the image processing unit 518 extracts a feature point of the vein on the basis of the image signal generated by the linear matrix unit 510.

The storage unit 1004 stores various data. The storage unit 1004 may store, for example, a frame that is an image signal for one screen, and may store data in a process of signal processing and authentication processing.

The authentication unit 1006 executes personal authentication on the basis of the data output from the signal processing unit 1002. The authentication unit 1006 executes the personal authentication on the basis of, for example, the wavelength of the rise analyzed by the spectrum analysis unit 512 and the fingerprint shape (feature point) based on the data output from the defect correction unit 508 and the like. Especially, in this embodiment, in a case where there is no peak around 760 nanometers of reduced hemoglobin, it may be determined that an imaging target is an artifact. Moreover, the authentication unit 1006 may analyze a rhythm of the peak around 760 nanometers of reduced hemoglobin, and determines that the imaging target is the artifact in a case where the rhythm is not observed. In this manner, the authentication unit 1006 may improve biometric authentication accuracy by capturing a signal of hemoglobin, that is, the rhythm of heart rate from the blood flow.

Personal information may be stored, for example, in the authentication unit 1006 as the wavelength range, the feature point of the fingerprint, and the feature point of the vein, or may be stored in the storage unit 1004. In a case where an object comes into contact with the cover glass 7, the authentication unit 1006 may determine that the object is the finger and may authenticate that this is a stored individual.

For example, the authentication unit 1006 acquires a shape characteristic of the fingerprint from an output from the image processing unit 518 and the like, and determines whether or not this coincides with a fingerprint of an authentication target using this information. For example, the authentication unit 1006 determines whether or not the feature point of the fingerprint stored in the storage unit 1004 coincides with the feature point of the authentication target. A general method may be used in the fingerprint authentication.

Furthermore, in a case where the spectrum analysis unit 512 detects the rise of the wavelength regarding the vein, the authentication unit 1006 determines that the object in contact with the cover glass 7 is a living body using this data.

Moreover, the authentication unit 1006 acquires the shape characteristic of the vein from the output from the image processing unit 518 and the like, and determines whether or not this coincides with the vein of the authentication target using this information. For example, the authentication unit 1006 compares a predetermined number of feature points extracted from the vein with the feature point stored in the storage unit 1004, thereby authenticating whether or not this is the stored individual. A general method may be used in the vein authentication.

The result output unit 1008 outputs a personal authentication result on the basis of the result output from the authentication unit 1006, too. For example, in a case where this coincides with the individual recorded in the storage unit 1004, the result output unit 1008 outputs a signal of authentication OK to the display unit 2 in a case where the finger in contact with the cover glass 7 at that timing coincides with the data of the recorded individual, and outputs a signal of authentication NG to the display unit 2 in other cases.

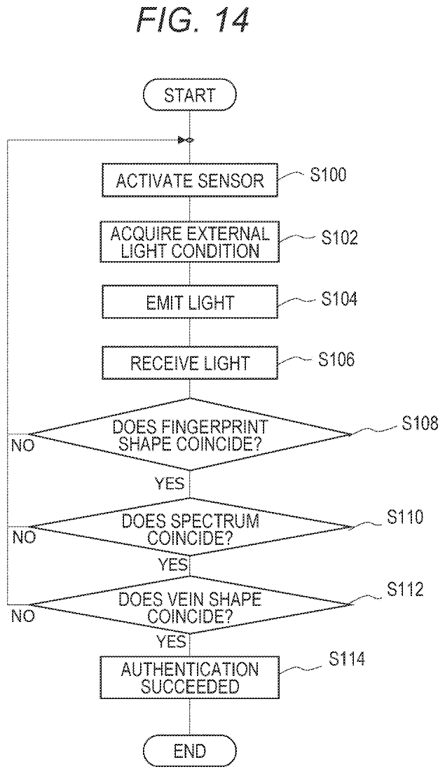

FIG. 14 is a flowchart illustrating a flow of processing of the electronic device 1 according to this embodiment. As an example, a case where the electronic device 1 performs the personal authentication using the fingerprint, spectrum, and vein is described.

First, the electronic device 1 activates the imaging unit 8 as the fingerprint sensor (S100). By activating, for example, the above-described components may be energized to be put into a standby state. The electronic device 1 may explicitly activate the fingerprint sensor by a switch and the like. As another example, it is possible to optically or mechanically acquire contact of an object on a reading surface (cover glass) 7, and the fingerprint sensor may be activated using this acquisition as a trigger. As still another example, it may be triggered by detecting that the finger approaches the reading surface (cover glass) 7 so as to be closer than a predetermined distance.

Next, the imaging unit 8 detects intensity of the light incident at that timing, and acquires a condition of external light on the basis of the result (S102). For example, the electronic device 1 acquires an image in a state in which light from inside is not incident. With this acquisition, intensity of light transmitted through the finger of the sunlight and indoor light, or intensity of light entering through a space between the fingers is detected. On the basis of the intensity of the light, the clamp unit 504 may execute ground processing in a subsequent process.

Next, a light emission unit provided in the electronic device 1 emits light to irradiate at least a part of a region where the finger and the cover glass 7 are in contact with each other (S104). The light emission may be white light or light having a specific wavelength, for example, light emission of R, G, B and the like. For example, since light on a long wavelength side is transmitted through the finger, B (and G) may be emitted in order to acquire a surface shape. Furthermore, infrared light may be emitted to observe the vein. For spectral analysis, light emission of R may be performed. In this manner, as the light emission, an appropriate color may be emitted on the basis of subsequent processing. These lights do not need to be emitted at the same timing. For example, it is also possible to emit R first to acquire data for spectral analysis, and then emit B and G to acquire data for shape analysis.

Next, the imaging unit 8 receives light, which is light emitted from the display panel 4a and reflected by the cover glass 7 with information of the fingerprint and the like included (S106). Light reception is executed by the imaging unit 8 described above, and thereafter, subsequent necessary processing is executed. For example, following the light reception, processing of acquiring the shape of the fingerprint and acquiring the spectrum of the reflected light or the transmitted light is executed through A/D conversion and background correction.

Next, the authentication unit 1006 determines whether or not the shape of the fingerprint coincides (S108). The determination of the shape of the fingerprint may be performed by a general method. For example, the authentication unit 1006 extracts a predetermined number of feature points from the fingerprint, compares the extracted feature points, and determines whether or not this may be determined as a stored individual.

In a case where the fingerprint shape does not coincide (S108: NO), the processing from S100 is repeated. Furthermore, in a case where the fingerprint shape does not coincide, the authentication unit 1006 may allow a light emitting region of the light emission unit 4a to emit light only in a corresponding region of a position in which the finger (living body) is placed. Therefore, it is possible to suppress generation of noise light of various reflection angles caused by allowing the display panel (light emission unit) 4a in a wide range to emit light. Therefore, authentication accuracy is further improved.

In a case where the fingerprint shape coincides (S108: YES), the authentication unit 1006 subsequently determines whether or not the spectrum coincides (S110). The authentication unit 1006 compares a result of the spectrum analyzed by the spectrum analysis unit 512 with a stored result of the individual and executes this determination. For example, the determination is made on the basis of whether or not the acquired spectrum is present within an allowable range from the stored spectrum of the rise of the skin color. In this manner, the personal authentication may be performed not only by the fingerprint shape but also by the spectrum.

In a case where the spectrum does not coincide (S110: NO), the processing from S100 is repeated.

In a case where the spectrum coincides (S110: YES), the authentication unit 1006 subsequently determines whether or not the vein shape coincides (S112). The authentication unit 1006 compares the feature point of the vein shape with the stored feather point of the individual and executes this determination. In this manner, the personal authentication may be performed not only by the fingerprint shape but also by the spectrum and the vein shape.

In a case where the vein shape does not coincide (S112: NO), the processing from S100 is repeated.

In a case where the vein shape coincides (S112: YES), the authentication unit 1006 determines that the authentication is successful (S114), and outputs the authentication result from the result output unit 1008. In this case, the result output unit 1008 outputs information indicating the fact that the authentication is successful, and allows access to another configuration of the electronic device 1, for example. Note that, in the above description, the output is performed in a case where the result output unit 1008 has succeeded, but there is no limitation. In a case of S108: NO, S110: NO, and S112: NO described above also, it is possible to notify the light emission unit, the imaging unit 8 and the like of the fact that the authentication fails via the result output unit 1008, and to acquire the data again.

Note that, the processing is repeated in a case where the authentication fails in the description above, but for example, in a case where repetition continues a predetermined number of times, access to the electronic device 1 may be blocked without performing the authentication any more. In this case, it is possible to prompt the user to input a passcode and the like using another access means, for example, a numeric keypad from the interface. Furthermore, in such a case, there is a possibility of failure in reading of the device, so that the authentication processing may be repeated while changing the light emission, the light reception, the state of the reading surface, the spectrum being used and the like. For example, in a case where an analysis result of being wet with water is acquired, some output may be performed via the interface to the user to wipe the water and perform the authentication operation again.

As described above, according to this embodiment, the ¼ wavelength plate 4b and the polarizing plate 4c are provided. Therefore, the signal component from the fingerprint of the optical path L1 reaches the fingerprint sensor 8 to be imaged, and the noise light of the optical path L2 reflected by the polarizing plate 6a is reflected by the polarizing plate 4c and cannot reach the fingerprint sensor 8. Therefore, the S/N ratio is improved, and the authentication accuracy of the authentication unit 1006 is improved.

### Variation of First Embodiment

A variation of the first embodiment is different from the first embodiment in that a reflectance of a region of an imaging unit 8 and a reflectance of another region coincide with each other in a case where light is incident from a cover glass 7. Hereinafter, a difference from the first embodiment is described.

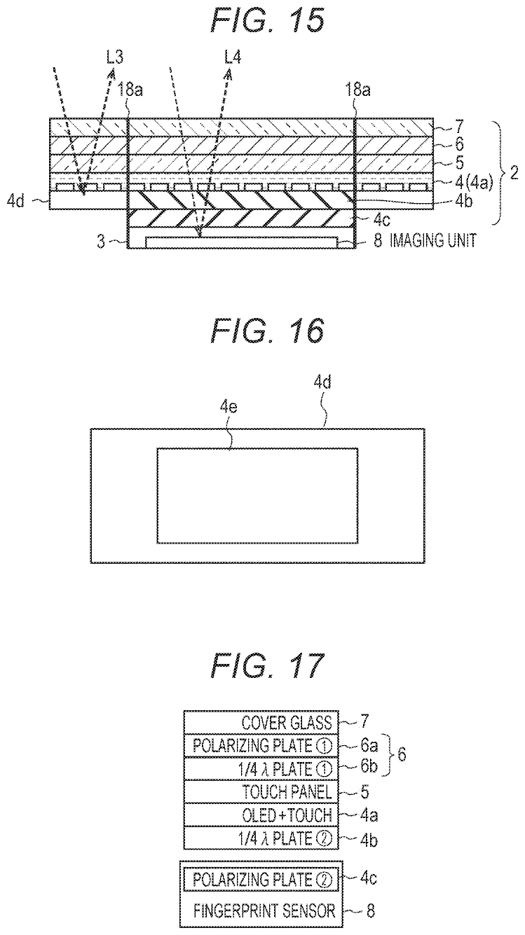

FIG. 15 is a schematic cross-sectional view of an electronic device 1 according to a variation of the first embodiment. The electronic device 1 in FIG. 15 includes components such as a battery, a communication circuit, a microphone, and a speaker not illustrated, and is often provided under a display unit 2. When strong light such as sunlight is incident through a cover glass 7 out of doors, a position and a shape of each component are visually recognized by a user, and there is a possibility that a feeling of strangeness in appearance is given. As a countermeasure, an opaque cover 4d is provided on a back side of the display unit 2. By using the opaque cover 4d, components provided under the display unit 2 are not visually recognized by the user. When a reflector is used as the cover 4d, not only a problem in appearance is solved, but also luminance of the display unit 2 may be increased by contribution of reflected light. In a case where the reflector is used, the cover 4d often mainly includes a material of metal such as copper and aluminum.

However, in a case where an imaging unit 8 is provided under the display unit 2, the opaque cover 4d cannot be provided immediately above, and a window 4e for transmitting light is required. When strong incident light is incident through the cover glass 7, the window 4e might give a feeling of strangeness in appearance. As a countermeasure, a circularly polarizing plate 6 is provided, but there is no perfect polarizing plate or ¼ wavelength plate, and furthermore, variations in film thickness and angle error at the time of attachment also affect, and it is difficult to completely eliminate external light reflection.

In view of such a circumstance, the electronic device 1 according to the variation of the first embodiment is configured so that, in a case where light is incident from the cover glass 7, a difference in light amount between light L3 reflected by the cover 4d and emitted out of the cover glass and light L4, which is light passing through the window 4e and reflected out of the cover glass, illustrated in FIG. 15 becomes small.

For example, in a case where the cover 4d is provided as the reflector and mainly includes a material of metal such as copper and aluminum, a polarizing plate 4c is provided as a reflection type, for example, a wire grid polarization element. It is more desirable that, if the cover 4d is mainly of a material of aluminum, a reflection layer of a wire grid is mainly of a material of aluminum, too, and if the cover 4d is mainly of a material of copper, the reflection layer of the wire grid is mainly of a material of copper, too, so that spectra of reflection light coincide with each other.

In contrast, external light such as the sun passes through a polarizing plate 6a and two ¼ wavelength plates 4b and 6b to become linearly polarized light, and a transmission axis of the polarizing plate 4c is provided so as to coincide with the linearly polarized light. That is, even if the main material of the reflection layer of the wire grid is made the same as that of the cover 4d, it is difficult to contribute to reduce the difference in light amount between the light L3 and the light L4 as it is. As a countermeasure, a width of a metal portion of the wire grid polarization element may be increased in order to increase reflection of polarized light in the transmission axis. Although a transmittance of the wire grid polarization element is reduced, visibility of the window 4e due to external light reflection may be weakened. As a result of actual machine verification in some cases, with a sufficient thickness of the wire grid polarization element of the polarizing plate 4c of at least 300 nanometers or more, and with a width of the metal portion of at least 200 nanometers or more, preferably 300 nanometers or more, an effect of suppressing appearance visibility may be acquired.

In contrast, in a case where the reflectance of the cover 4d is low, the polarizing plate 4c may be provided as an absorption type. Specifically, the absorption type is acquired by dyeing a PVA film with an iodine-based material or a dye-based material such as a dichroic dye and stretching the same.

Alternatively, in a case where the reflectance of the cover 4d is low, the polarizing plate 4c may include a wire grid polarization element 150 provided with a light absorption layer. More specifically, in FIG. 7, for example, the wire grid polarization element 150 acquired by depositing a light absorption layer 53 on which antireflection tungsten is deposited may be formed on a light reflection layer 51 of aluminum having high reflectance, and the reflectance may be balanced by W film thickness control. In this manner, since the wire grid polarization element 150 includes the light reflection layer 51 and the light absorption layer 53, the reflectance may be adjusted by adjusting a thickness and a material of each of the light reflection layer 51 and the light absorption layer 53. Alternatively, in the polarizing plate 4c, a difference in reflectance may be reduced by forming the imaging unit 8 side with a reflection type polarization element and forming the display unit 2 side with an absorption type polarization element.

Alternatively, by shifting a phase of the ¼ wavelength plate 4b in a vertically upper region of the window 4e, an orthogonal relationship with the polarizing plate 6a collapses, and an amount of light emitted from the cover glass 7 may be changed. Specifically, a region corresponding to the window 4e may be hollowed out from the ¼ wavelength plate 4b, and another ¼ wavelength plate having the same outer shape and shifted in phase may be fitted. As the phase to be shifted at that time, an angle at which the visibility of the window 4e is lost may be acquired by an experiment.

As described above, according to the variation of the first embodiment, the material, thickness, angle, or line width of the optical element included in the display unit 2 is adjusted so that the reflectance of light in the vertically upper region of the imaging unit 8 is the same as the reflectance of light in another region. Therefore, even if the incident light is incident via the cover glass 7, the amount of reflected light reflected via the cover glass 7 is made uniform.

### Second Embodiment

An electronic device 1 according to a second embodiment is different from the electronic device 1 according to the first embodiment in that a polarizing plate 4c is formed in a fingerprint sensor 8. Hereinafter, a difference from the electronic device 1 according to the first embodiment is described.

FIG. 17 is a schematic diagram in a case where the polarizing plate 4c is formed in the fingerprint sensor 8 (an imaging unit 8). As illustrated in FIG. 17, in the electronic device 1 according to this embodiment, the polarizing plate 4c is formed in the fingerprint sensor 8. Furthermore, optical characteristics of ¼ wavelength plates 4b and 6b and polarizing plates 4c and 6a may be made equivalent to the optical characteristics illustrated in FIG. 10 or 11. That is, as illustrated in FIG. 10, a slow axis of the ¼ wavelength plate 6b is different from a transmission axis of the polarizing plate 6a by 45 degrees or 135 degrees. Furthermore, the transmission axis of the polarizing plate 6a and a transmission axis of the polarizing plate 4c are orthogonal to each other. A slow axes of the ¼ wavelength plate 6b and the ¼ wavelength plate 4b are the same. Alternatively, as illustrated in FIG. 11, the slow axis of the ¼ wavelength plate 6b is different from the transmission axis of the polarizing plate 6a by 45 degrees or 135 degrees. Furthermore, the transmission axes of the polarizing plate 6a and the polarizing plate 4c are the same. The slow axes of the ¼ wavelength plate 6b and the ¼ wavelength plate 4b are orthogonal to each other.

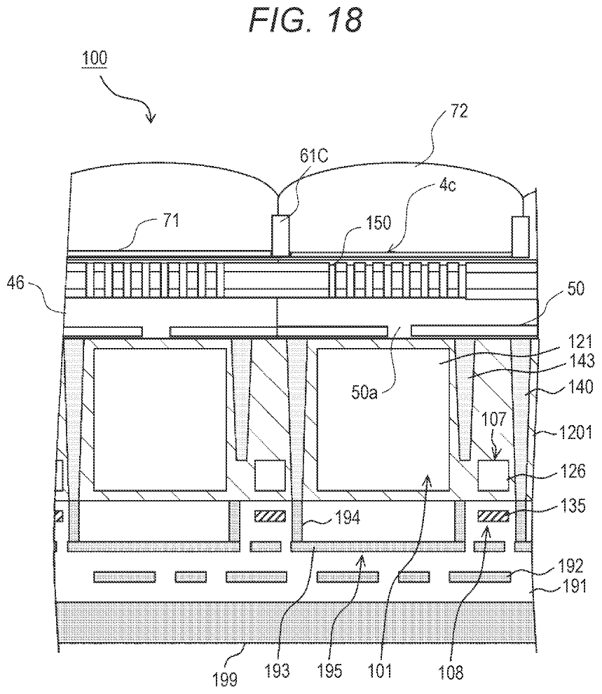

FIG. 18 is a diagram illustrating an example of a cross-sectional structure of a pixel 100 in a case where the polarizing plate 4c is formed in the fingerprint sensor 8 (the imaging unit 8). As illustrated in FIG. 18, the pixel 100 is provided with a polarizing plate 4c, an underlying insulating layer 46, a first light shielding film 50, a bank 61C, a color filter 71, an on-chip lens 72, a semiconductor substrate 1201, a separation region 140, a flattening film 183, an insulating layer 191, a wiring layer 192, and a support substrate 199. Note that the insulating layer 191 and the wiring layer 192 form a wiring region.

The first light shielding film 50 including a pinhole 50a is deposited on a photoelectric conversion unit (light receiving region) 101. The above-described first light shielding film 50 shields a charge holding unit 107 to be described later. The underlying insulating layer 46 including a flattening layer as a lower layer is formed on the first light shielding film 50, and the polarizing plate 4c including a wire grid polarization element 150, the color filter 71, and the on-chip lens 72 are formed on the underlying insulating layer 46.

The bank 61C includes, for example, a metal film. A lens material may be dammed by the bank 61C in a reflow treatment when forming a reflow lens. For example, in the reflow treatment, the material of the reflow lens 72 is dammed over an entire region of the bank 61C, and a shape of the reflow lens 72 is stabilized.

The semiconductor substrate 1201 is a substrate in which a semiconductor portion of an element forming a pixel circuit is formed. The semiconductor portion of the element is formed in a well region formed in the semiconductor substrate 1201. The semiconductor substrate 1201 in the drawing is formed in a p-type well region. An n-type semiconductor region 121 is formed in the semiconductor substrate 1201 to form the semiconductor portion of the element.

The n-type semiconductor region 121 forms the photoelectric conversion unit 101. More specifically, a photodiode including the n-type semiconductor region 121 and a pn junction of an interface of the p-type well region around the n-type semiconductor region 121 form the photoelectric conversion unit 101. A charge generated by photoelectric conversion is accumulated in the n-type semiconductor region 121. The n-type semiconductor region 122 forms the charge holding unit 107 of a floating diffusion system. Furthermore, a MOS transistor 108 is arranged between the n-type semiconductor regions 121 and 122. The MOS transistor 108 makes the n-type semiconductor regions 121 and 122 a source and a drain, respectively, and makes the p-type well region therebetween a channel. Note that a gate 135 is arranged adjacently to the channel of the MOS transistor 108. For convenience, the insulating layer 191 between the semiconductor substrate 1201 and the gate 135 corresponds to a gate insulating film.

The semiconductor substrate 1201 may have a thickness of 3 μm, for example. Furthermore, a p-type semiconductor region for pinning may be arranged in the vicinity of a back surface of the semiconductor substrate 1201. Therefore, noise based on an interface state may be reduced.

A wiring region including the wiring layer 192 and the insulating layer 191 to be described later is arranged on a front surface side of the semiconductor substrate 1201. In contrast, a fixed charge film 1410 (not illustrated) for enhancing the pinning described above and an oxide film 142 (not illustrated) for protecting and insulating the semiconductor substrate 1201 are arranged on the back surface side of the semiconductor substrate 1201.

The fixed charge film 1410 may include, for example, an oxide or nitride including at least one of hafnium (Hf), aluminum (Al), zirconium (Zr), tantalum (Ta), or titanium (Ti). Furthermore, the fixed charge film 1410 may be formed by chemical vapor deposition (CVD), sputtering, and atomic layer deposition (ALD). In a case where the ALD is adopted, it is possible to simultaneously form an SiO₂ film that reduces the interface state during the deposition of the fixed charge film 1410, which is preferable. Furthermore, it may also include an oxide or nitride including at least one of lanthanum (La), cerium (Ce), neodymium (Nd), promethium (Pm), samarium (Sm), europium (Eu), gadolinium (Gd), terbium (Tb), dysprosium (Dy), holmium (Ho), thulium (Tm), ytterbium (Yb), lutetium (Lu), or yttrium (Y). Furthermore, the fixed charge film 1410 may include hafnium oxynitride or aluminum oxynitride. Alternatively, silicon (Si) or nitrogen (N) may be added to the fixed charge film 1410 in an amount that does not impair an insulating property. Therefore, heat resistance and the like may be improved.

The oxide film 142 may include, for example, SiO₂. This is formed into a thickness of 100 nm or less, more preferably 30 to 60 nm by the ALD.

The wiring layer 192 is a conductor that wires an element formed in the semiconductor substrate 1201. The wiring layer 192 includes metal such as Cu. The insulating layer 191 insulates the wiring layer 192. The insulating layer 191 may include an insulating material, for example, SiO₂. The wiring layer 192 and the insulating layer 191 may be formed in multiple layers.

The separation region 140 is a region that separates the photoelectric conversion units 101 of the adjacent pixels 100. The separation region 140 is arranged in the vicinity of a boundary between the pixels 100, and may prevent an inflow of the charge from the adjacent pixel 100 by ion implantation. Furthermore, by forming a trench in the separation region 140 and embedding an insulating film having a different refractive index, not only the inflow of charge may be prevented, but also light obliquely incident from the adjacent pixel 100 may be shielded. In a case where the trench is formed in the separation region 140, processing may be performed from the back surface side toward the front surface side of the semiconductor substrate 1201, and further processing may be performed so as to penetrate the semiconductor substrate 1201. The separation region 140 may include a material that shields light, for example, metal in a clearance formed after the insulating film is embedded. In further detail, this may include Al, silver (Ag), gold (Ag), copper (Cu), platinum (Pt), molybdenum (Mo), chromium (Cr), Ti, nickel (Ni), W, iron (Fe), tellurium (Te) and the like, or an alloy including these metals. Furthermore, this may be formed by stacking a plurality of these materials. Furthermore, it is possible to arrange Ti, titanium nitride (TiN), and a film formed by stacking them between the same and the oxide film 142 as an adhesion layer.

Note that, in a case where Al is adopted as the material of the separation region 140, sensitivity of the pixel 100 may be improved, which is preferable. This is because Al has a relatively high reflectance, and light transmitted through the photoelectric conversion unit 101 (n-type semiconductor region 121) to be incident on the separation region 140 is reflected to be returned to the photoelectric conversion unit 101. The separation region 140 of Al may be formed by a known method, for example, high-temperature sputtering.

A groove in which the separation region 140 is arranged may be formed by dry-etching the semiconductor substrate 1201, for example. By embedding the above-described insulating film or metal material in the groove, the separation region 140 may be arranged. This may be performed by, for example, physical vapor deposition (PVD) such as sputtering or vacuum vapor deposition, CVD, plating, and a coating method.

The second separation region 143 is a separation region arranged between the photoelectric conversion unit 101 and the second charge holding unit 107. The second separation region 143 is arranged in a groove formed in the semiconductor substrate 1201. Unlike the separation region 140, the groove in which the second separation region 143 is formed does not penetrate the semiconductor substrate 1201, and a bottom thereof is formed in a relatively shallow position on the front surface side of the semiconductor substrate 1201. Therefore, an opening is formed between the bottom of the second separation region 143 and the front surface of the semiconductor substrate 1201, and the channel of the MOS transistor 108 is formed in the opening. By arranging the second separation region 143, it is possible to suppress the inflow of charge from the photoelectric conversion unit 101 to the charge holding unit 107.

The charge holding unit 107 holds the charge during a period from an end of an exposure period to an output of an image signal. During this holding period, for example, exposure of a next frame is started in the photoelectric conversion unit 101. At that time, when the charge flows from the photoelectric conversion unit 101 into the second charge holding unit 107, an image signal of a different frame is mixed as noise. Therefore, by arranging the second light shielding region 143 between the photoelectric conversion unit 101 and the second charge holding unit 107 except for a channel region of the MOS transistor 108, it is possible to suppress the inflow of charge and to reduce mixing of noise. Furthermore, by arranging the second light shielding region 143, light incident on the second charge holding unit 107 from the region of the photoelectric conversion unit 101 may be shielded, and mixing of noise based on the incident light may be reduced.

A lid 195 is arranged in the insulating layer 191 in the wiring region and shields the incident light transmitted through the photoelectric conversion unit 101. The lid 195 includes a wall 194 and a bottom 193. The lid 195 covers a space between the photoelectric conversion unit 101 and the wiring layer 192 in a lid shape to shield light. A part of the light incident on the pixel 100 is transmitted without contributing to photoelectric conversion in the photoelectric conversion unit 101. When the transmitted light is reflected by the wiring layer 192 in the wiring region and is incident on the photoelectric conversion unit 101 of another pixel 100, noise is mixed in another pixel 100, and an image quality is deteriorated. Therefore, by arranging the lid 195, reflection of the incident light transmitted through the photoelectric conversion unit 101 by the wiring layer 192 is prevented. The wall 194 and the bottom 193 may include metal such as Cu as is the case with the wiring layer 192.

The separation region 140 and the second separation region 143 are formed by arranging a material such as W or Al, for example, in the grooves formed in the semiconductor substrate 1201. The groove in which the separation region 140 is arranged is formed deeper than the groove in which the second separation region 143 is arranged. This may be performed, for example, by forming the grooves in two stages. First, the semiconductor substrate 1201 is etched, and the grooves having a depth corresponding to the second separation region 140 is formed in a position in which the separation region 143 and the second separation region 143 are to be formed. Next, the groove in which the second separation region 143 is to be arranged is protected by a resist and the like, and the etching is performed again to the groove in which the separation region 140 is to be arranged. Therefore, the grooves having different depths may be formed. Next, a material forming the separation region 140, the second separation region 143, and the polarization element 150, for example, a film of W or Al is deposited on the semiconductor substrate 1201 and arranged in these grooves. Through the above-described steps, the separation region 140 and the second separation region 143 may be formed.

Stray light from a gap may be effectively suppressed by the metal film included in the bank 61C. Furthermore, since the wire grid polarization element 150 may be provided in proximity to the photoelectric conversion unit 101, leakage of light (polarization crosstalk) to an adjacent imaging element may be prevented.

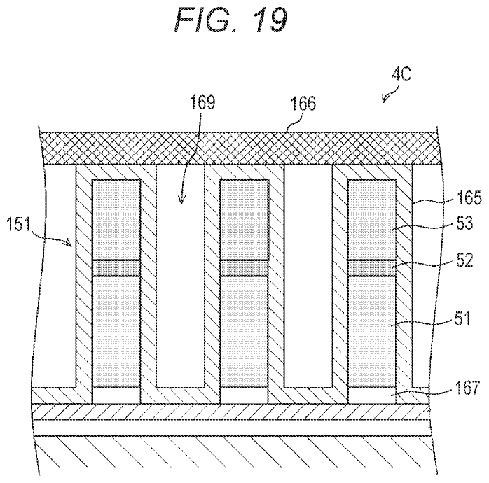

Here, a detailed configuration of the polarizing plate 4c in FIG. 18 is described. FIG. 19 is a diagram illustrating a configuration example of the polarizing plate 4c according to this embodiment. In addition to the light reflection layer 51, the insulating layer 52, and the light absorption layer 53 described above, the polarizing plate 4c includes an adhesion layer 167, a sidewall protection layer 165, an upper protection layer 166, and a gap 169.

The adhesion layer 167 is arranged between the underlying insulating layer 46 and the light reflection layer 51 to improve adhesion strength of the light reflection layer 51. For the adhesion layer 167, for example, Ti, TiN, and a film acquired by stacking them are used.

A gas such as air is sealed in the gap 169 between strip-shaped conductors 151. By adopting such an air gap structure, a transmittance of the polarizing plate 4c may be improved. This is because air and the like has a refractive index of approximately 1.

The sidewall protection layer 165 is arranged around the strip-shaped conductor 151 of the stacked light reflection layer 51, insulating layer 52, and light absorption layer 53, and mainly protects the sidewall of the strip-shaped conductor 151. In the air gap structure described above, a metal material or an alloy material forming the light reflection layer 51 and the light absorption layer 53 are in contact with air (outside air). By arranging the sidewall protection layer 165, it is possible to prevent corrosion and deterioration of the light reflection layer 51 and the like due to moisture and the like in the outside air. For example, a material having a refractive index of 2 or smaller and an extinction coefficient close to 0 is used for the sidewall protection layer 165. This makes it possible to reduce an influence on a polarization characteristic of the polarization element 150. More specifically, the sidewall protection layer 165 includes an insulating material of Si such as SiO₂, SiON, SiN, SiC, SiOC, and SiCN. Furthermore, the sidewall protection layer 165 may include a metal oxide such as aluminum oxide (AlOx), hafnium oxide (HfOx), zirconium oxide (ZrOx), and tantalum oxide (TaOx). The sidewall protection layer 165 may be formed by depositing these materials by a known method such as CVD, PVD, ALD, and a sol-gel method.

The upper protection layer 166 is a film arranged adjacently to an upper surface of the strip-shaped conductor 151 to close the gap 169. The upper protection layer 166 includes a material similar to that of the sidewall protection layer 165 described above. Furthermore, the upper protection layer 166 may be deposited by a depositing method in which the material is not deposited in the gap 169 but is deposited on the upper surface of the strip-shaped conductor 161, for example, the PVD.

The light reflection layer 51, the insulating layer 52, and the light absorption layer 53 are formed to have thicknesses of, for example, 150 nm, 25 nm, and 25 nm, respectively. By arranging the polarization element 150 having such a multi-layer configuration, reflected light from the polarization element 150 is reduced. Furthermore, by using the polarizing plate 4c having the air gap structure, the transmittance may be improved. In this manner, by arranging the polarizing plate 4c having a three-layer configuration, reflection from the polarizing plate 4c may be reduced.

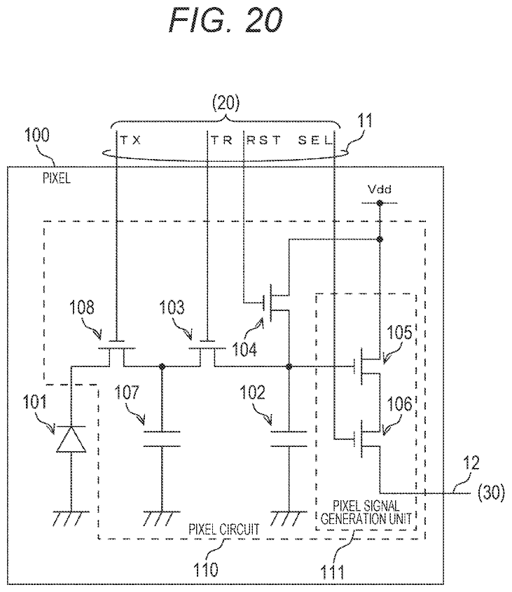

FIG. 20 is a diagram illustrating an example of a circuit configuration of the pixel 100 according to the second embodiment. As illustrated in FIG. 20, the pixel 100 is provided with the photoelectric conversion unit 101, a charge holding unit 102, the second charge holding unit 107, and MOS transistors 103 to 108.

A cathode of the photoelectric conversion unit 101 is connected to a source of the MOS transistor 108, and a gate of the MOS transistor 108 is connected to a transfer signal line TX. A drain of the MOS transistor 108 is connected to a source of the MOS transistor 103 and one end of the second charge holding unit 107. The other end of the second charge holding unit 107 is grounded. A drain of the MOS transistor 103 is connected to a source of the MOS transistor 104, a gate of the MOS transistor 105, and one end of the charge holding unit 102. The other end of the charge holding unit 102 is grounded. Drains of the MOS transistors 104 and 105 are commonly connected to a power supply line Vdd, and a source of the MOS transistor 105 is connected to a drain of the MOS transistor 106. A source of the MOS transistor 106 is connected to a signal line 12. Gates of the MOS transistors 103, 104, and 106 are connected to a transfer signal line TR, a reset signal line RST, and a selection signal line SEL, respectively. Note that the transfer signal line TR, the reset signal line RST, and the selection signal line SEL form a signal line 11.

The photoelectric conversion unit 101 generates the charge according to the applied light as described above. A photodiode may be used as the photoelectric conversion unit 101. Furthermore, the charge holding units 102 and 107 and the MOS transistors 103 to 108 form a pixel circuit.

The MOS transistor 103 is a transistor that transfers the charge generated by photoelectric conversion of the photoelectric conversion unit 101 to the charge holding unit 102. The transfer of the charge in the MOS transistor 103 is controlled by a signal transmitted by the transfer signal line TR. The charge holding unit 102 is a capacitor that holds the charge transferred by the MOS transistor 103. The MOS transistor 105 is a transistor that generates a signal based on the charge held in the charge holding unit 102. The MOS transistor 106 is a transistor that outputs the signal generated by the MOS transistor 105 to the signal line 12 as the image signal. The MOS transistor 106 is controlled by a signal transmitted by the selection signal line SEL.

The MOS transistor 104 is a transistor that resets the charge holding unit 102 by discharging the charge held in the charge holding unit 102 to the power supply line Vdd. The reset by the MOS transistor 104 is controlled by a signal transmitted by the reset signal line RST, and is executed before the charge is transferred by the MOS transistor 103. Note that, at the time of this reset, the photoelectric conversion unit 101 may also be reset by making the MOS transistor 103 conductive. In this manner, the pixel circuit converts the charge generated by the photoelectric conversion unit 101 into the image signal. Note that the MOS transistors 105 and 106 form an image signal generation unit 111.

The second charge holding unit 107 holds the charge generated by the photoelectric conversion unit 101. The second charge holding unit 107 holds the charge during a period from the end of the exposure to the start of the output of the image signal in the pixel 100.

The MOS transistor 108 is a transistor that transfers the charge generated by the photoelectric conversion unit 101 to the second charge holding unit 107.

Imaging of the imaging element 1 in which the pixel 100 including the pixel circuit in the drawing is arranged may be performed as follows. First, the MOS transistors 103, 104, and 108 are made conductive to reset the photoelectric conversion unit 101, the charge holding unit 102, and the second charge holding unit 107. This reset is simultaneously performed in all the pixels 100 arranged in the pixel array unit 10. Next, transition to a non-conductive state of the MOS transistors 103, 104, and 108 is made. Therefore, the exposure period is started. After a predetermined exposure period elapses, the MOS transistors 103 and 104 are made conductive again to reset the second charge holding unit 107 again, and then the MOS transistor 108 is made conductive to transfer the charge generated by the photoelectric conversion unit 101 to the second charge holding unit 107. Therefore, the exposure period is simultaneously stopped for all the pixels 100.

Next, the MOS transistor 104 is made conductive to reset the charge holding unit 102 again, and the MOS transistor 103 is made conductive to transfer the charge of the second charge holding unit 107 to the charge holding unit 102. Next, the MOS transistor 106 is made conductive and the image signal generated by the MOS transistor 105 is output to the signal line 12. Processing from the reset of the charge holding unit 102 to the output of the image signal is sequentially executed for each row from a first row of the pixel array unit 10. Therefore, the image signal of one frame may be output from the pixels 100. In this manner, by arranging the second charge holding unit 107 and temporarily holding the charge generated by the photoelectric conversion unit 101, it is possible to execute periods of the exposure and the output of the image signal separately. It becomes possible to simultaneously perform the exposure in all the pixels 100 arranged in the pixel array unit 10. Such imaging system is referred to as a global shutter system. Furthermore, after the charge is transferred to the second charge holding unit 107, exposure of a next frame may be started.

By adopting the global shutter system, a shift of the exposure period in each row as in a rolling shutter system does not occur, so that it is possible to reduce distortion and blur when imaging a moving subject.

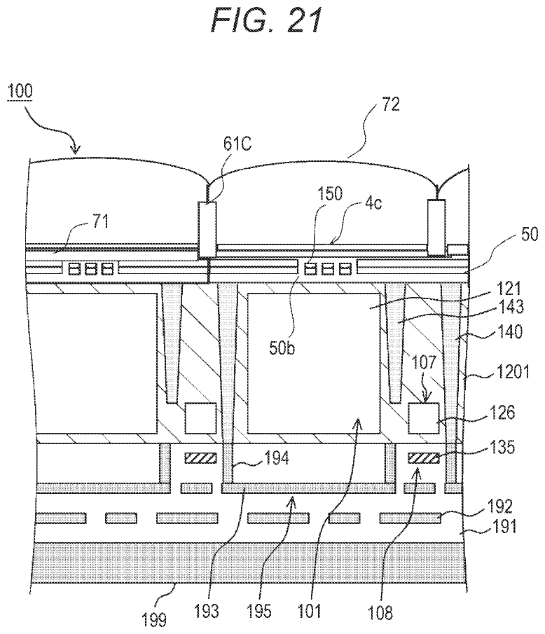

FIG. 21 is a schematic diagram in a case where the polarizing plate 4c is formed in the pinhole 50a of the first light shielding film 50. As illustrated in FIG. 21, the electronic device 1 illustrated in FIG. 21 is different from the electronic device 1 illustrated in FIG. 18 in that the polarizing plate 4c is formed in the pinhole 50a. In this manner, by providing the polarizing plate 4c in the pinhole 50, polarization separation also becomes possible. Furthermore, since the polarizing plate 4c is provided in a condensed region, a region of the polarizing plate 4c may be downsized.

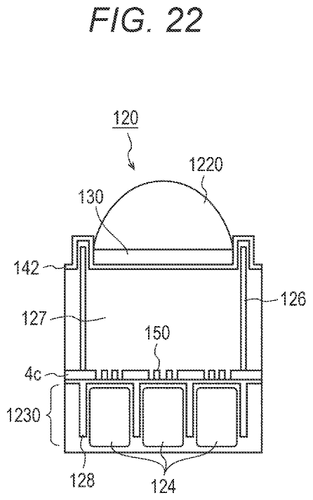

FIG. 22 is a schematic diagram in a case where the polarizing plate 4c is formed in a pixel 120. As illustrated in FIG. 22, the pixel 120 is provided with an on-chip lens 1220, a color filter 130 is provided below the on-chip lens, and the polarizing plate 4c is provided with a light shielding wall 126 for suppressing crosstalk interposed therebetween. Therefore, light polarized by the polarizing plate 4c may be imaged for each subpixel 124.

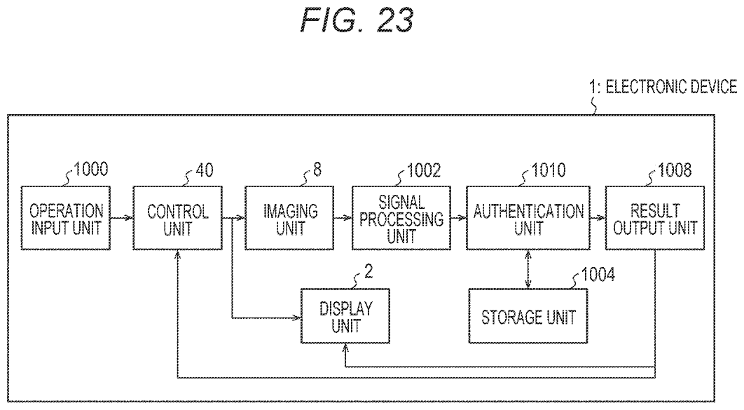

FIG. 23 is a block diagram illustrating a schematic configuration example of the electronic device 1, which is an example of the imaging device to which the present technology is applicable. The electronic device 1 is provided with the display unit 2 (FIGS. 1A and 1B), the imaging unit 8 (FIGS. 1A and 1B), the control unit 40 (FIG. 3), an operation input unit 1000, a signal processing unit 1002, an authentication unit 1010, a result output unit 1008, and a storage unit 1004.

The authentication unit 1010 according to this embodiment further has a so-called barcode reader function of authenticating a geometric shape in addition to the authentication function of the authentication unit 1006 according to the first embodiment. By adopting the global shutter system, a shift of the exposure period for each pixel row does not occur, so that the electronic device 1 according to this embodiment may reduce distortion when imaging a moving subject. Therefore, the authentication unit 1006 may perform authentication while moving the subject or the electronic device 1 and performing a scan operation in the authentication of the geometric shape. Similarly, the authentication unit 1006 may perform authentication while moving the subject or the electronic device 1 and performing a scan operation also in the biometric authentication. That is, in the biometric authentication, the authentication unit 1006 may perform the authentication by a flip operation without stopping the living body.

As described above, in the electronic device 1 according to this embodiment, the polarizing plate 4c is arranged in the pixel 100 (120). Therefore, the light may be polarized in the pixel 100 (120), and the polarized light may be imaged by the photoelectric conversion unit 101 (124). Furthermore, since the wire grid polarization element 150 may be provided in proximity to the photoelectric conversion unit 101 (124), leakage of light (polarization crosstalk) to an adjacent photoelectric conversion unit 101 (124) may be prevented.

### Third Embodiment

An electronic device 1 according to a third embodiment is different from the electronic device 1 according to the second embodiment in that a ¼ wavelength plate 4b is further formed in a fingerprint sensor 8. Hereinafter, a difference from the electronic device 1 according to the second embodiment is described.

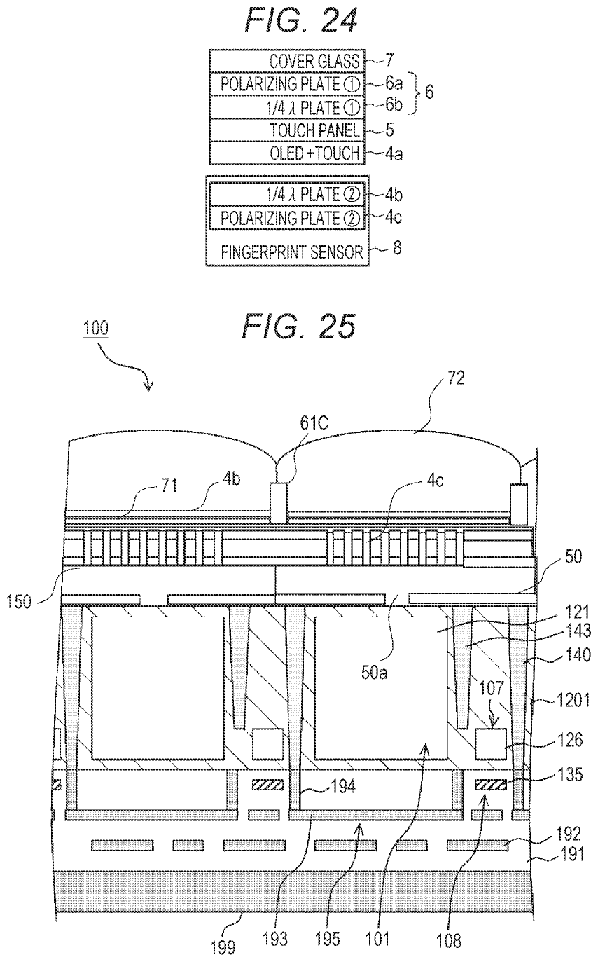

FIG. 24 is a schematic diagram in a case where the ¼ wavelength plate 4b is further formed in the fingerprint sensor 8. As illustrated in FIG. 24, in the electronic device 1 according to this embodiment, the ¼ wavelength plate 4b and a polarizing plate 4c are formed in the fingerprint sensor 8. Furthermore, optical characteristics of ¼ wavelength plates 4b and 6b and polarizing plates 4c and 6a may be made equivalent to the optical characteristics illustrated in FIG. 10 or 11. That is, as illustrated in FIG. 10, a slow axis of the ¼ wavelength plate 6b is different from a transmission axis of the polarizing plate 6a by 45 degrees or 135 degrees. Furthermore, the transmission axis of the polarizing plate 6a and the transmission axis of the polarizing plate 6a are orthogonal to each other. A slow axes of the ¼ wavelength plate 6b and the ¼ wavelength plate 4b are the same. Alternatively, as illustrated in FIG. 11, the slow axis of the ¼ wavelength plate 6b is different from the transmission axis of the polarizing plate 6a by 45 degrees or 135 degrees. Furthermore, the transmission axes of the polarizing plate 6a and the polarizing plate 6a are the same. The slow axes of the ¼ wavelength plate 6b and the ¼ wavelength plate 4b are different by 90 degrees.

FIG. 25 is a diagram illustrating a cross-sectional structure of the pixel 100 in a case where the ¼ wavelength plate 4b is further formed in the fingerprint sensor 8. As illustrated in FIG. 23, in the pixel 100, the ¼ wavelength plate 4b is stacked under the color filter 71. Therefore, it is possible to perform linear polarization in the pixel 100, and the polarized light may be imaged by the photoelectric conversion unit 101.

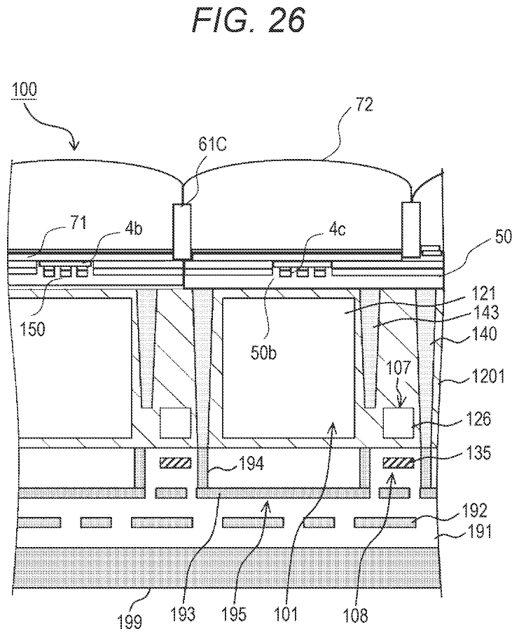

FIG. 26 is a schematic diagram in a case where the ¼ wavelength plate 4b and the polarizing plate 4c are formed in the pinhole 50a of the first light shielding film 50. As illustrated in FIG. 25, the electronic device 1 illustrated in FIG. 20 is different from the electronic device 1 illustrated in FIG. 18 in that the ¼ wavelength plate 4b is provided and the polarizing plate 4c is formed in the pinhole 50a. By providing the ¼ wavelength plate 4b and the polarizing plate 4c in this manner, it is possible to perform linear polarization and the polarized light may be imaged by the photoelectric conversion unit 101. Furthermore, since the ¼ wavelength plate 4b and the polarizing plate 4c are provided in the imaging device, it is also possible to reduce a thickness and size of the regions of the ¼ wavelength plate 4b and the polarizing plate 4c.

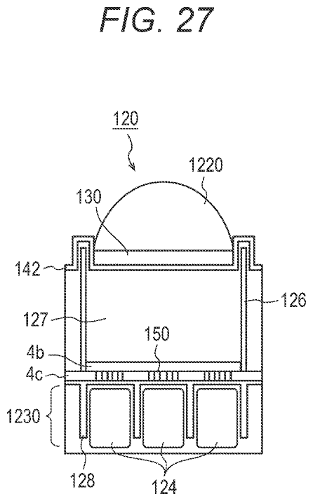

FIG. 27 is a schematic diagram in a case where the ¼ wavelength plate 4b and the polarizing plate 4c are formed in the pixel 120. As illustrated in FIG. 26, the pixel 120 is provided with an on-chip lens 1220, a color filter 130 is provided below the on-chip lens, and the polarizing plate 4c is provided with a light shielding wall 126 for suppressing crosstalk interposed therebetween. Moreover, the ¼ wavelength plate 4b is provided on the polarizing plate 4c. Therefore, it is possible to perform linear polarization and image the polarized light for each subpixel 124.

As described above, in the electronic device 1 according to this embodiment, the ¼ wavelength plate 4b and the polarizing plate 4c are arranged in the pixel 100 (120). Therefore, it is possible to perform linear polarization in the pixel 100 (120), and the polarized light may be imaged by the photoelectric conversion unit 101 (124).

Note that, the present technology may also have following configurations.

(1)

An electronic device provided with:

sequentially from one side to the other side,

a first polarizing plate that makes incident light linearly polarized light;

a first ¼ wavelength plate a slow axis of which is different from an absorption axis of the first polarizing plate by 45 degrees or 135 degrees;

a self-luminous element layer;

a second ¼ wavelength plate a slow axis of which is in the same direction as the slow axis of the first ¼ wavelength plate;

a second polarizing plate an absorption axis of which is orthogonal to the absorption axis of the first polarizing plate; and

an imaging device that images light via the second polarizing plate.

(2)

An electronic device provided with:

sequentially from one side to the other side,

a first polarizing plate that makes incident light linearly polarized light;

a first ¼ wavelength plate a slow axis of which is different from an absorption axis of the first polarizing plate by 45 degrees or 135 degrees;

a self-luminous element layer;

a second ¼ wavelength plate a slow axis of which is different from the slow axis of the first ¼ wavelength plate by 90 degrees;

a second polarizing plate an absorption axis of which is in the same direction as the absorption axis of the first polarizing plate; and

an imaging device that images light via the second polarizing plate.

(3)

The electronic device according to (1) or (2), in which the second polarizing plate is provided in a pixel structure of the imaging device.

(4)

The electronic device according to (1) or (2), in which

the self-luminous element layer is a display including a self-luminous element,

the imaging device is an imaging device that images scattered light of a finger irradiated with light of the self-luminous element via the first ¼ wavelength plate and the first polarizing plate, and images the scattered light of the finger as a fingerprint image via the first polarizing plate, the first ¼ wavelength plate, the self-luminous element layer, the second ¼ wavelength plate, and the second polarizing plate, and

the electronic device further includes:

a signal processing unit that extracts a feature point from the fingerprint image;

a storage unit that stores a feature point of a fingerprint of an authentication target; and

an authentication unit that collates the feature point extracted from the fingerprint image with the feature point of the fingerprint of the authentication target to determine whether or not the feature points coincide with each other.

(5)

The electronic device according to (1) or (2), in which

the imaging device is an imaging device that images an authentication target irradiated with light of the self-luminous element via the first ¼ wavelength plate and the first polarizing plate, and images light from the authentication target via the first polarizing plate, the first ¼ wavelength plate, the self-luminous element layer, the second ¼ wavelength plate, and the second polarizing plate,

the imaging device outputs an image signal on the basis of incident light incident via an optical member with a different transmission characteristic of a wavelength, and

the electronic device further includes an authentication unit that determines that an imaging target is an artifact in a case where there is no rise in a wavelength region of 500 to 600 nanometers.

(6)

The electronic device according to (1) or (2), in which

the imaging device is an imaging device that images an authentication target irradiated with light of the self-luminous element via the first ¼ wavelength plate and the first polarizing plate, and images light from the authentication target as a vein image via the first polarizing plate, the first ¼ wavelength plate, the self-luminous element layer, the second ¼ wavelength plate, and the second polarizing plate, and

the electronic device further includes:

a signal processing unit that extracts a feature point from the vein image;

a storage unit that stores a feature point of a vein of the authentication target; and

an authentication unit that collates the feature point extracted from the vein image with the feature point of the vein of the authentication target to determine whether or not the feature points coincide with each other.

(7)

The electronic device according to (1) or (2), in which the self-luminous element layer is an organic light emitting diode.

(8)

The electronic device according to (1) or (2), in which

the imaging device includes:

an on-chip lens; and

a metal light shielding film including a pinhole corresponding to a position in which the on-chip lens condenses light.

(9)

The electronic device according to (8), in which

the imaging device further includes:

a metal wire grid polarization element in the pinhole.

(10)

The electronic device according to (1) or (2), in which

the imaging device includes a pixel array including a plurality of pixels, and

a pixel includes:

a plurality of subpixels each including a photoelectric conversion element that receives light incident at a predetermined angle and outputs an analog signal on the basis of intensity of the received light; and

an on-chip lens that condenses the incident light on a subpixel.

(11)

The electronic device according to (10), in which a metal wire grid polarization element is formed in at least one of the subpixels.

(12)

The electronic device according to (3), in which the wire grid polarization element is a structure formed by stacking a light reflection layer including a first conductive material and a light absorption layer including a second conductive material on the reflection layer.

(13)

The electronic device according to (1) or (2), in which

the imaging device includes a color filter in a pixel, and

a difference between a wavelength corresponding to a spectrum center of gravity of the color filter and a wavelength corresponding to an emission spectrum center of gravity of the self-luminous element layer at the time of authentication is +50 nm or smaller.

(14)

The electronic device according to (1) or (2), in which

in the second polarizing plate, a reflection type polarizing filter and an absorption type polarizing filter are stacked.

(15)

The electronic device according to (1) or (2), in which

the second polarizing plate includes a wire grid polarization element, and

is a structure formed by stacking a light reflection layer including a first conductive material and a light absorption layer including tungsten or a tungsten compound on the light reflection layer.

(16) The electronic device according to (1) or (2), in which in a case where a film thickness of the second ¼ wavelength plate is set to T, a refractive index of a normal light beam is set to ne, and a refractive index of an abnormal light beam is set to no, a difference between 4×T×(ne−no), which is a target wavelength, and an emission spectrum center of gravity of the self-luminous element layer at the time of authentication is 0.05 um or smaller.

(17)

The electronic device according to (1) or (2), in which in a case where light emission of the self-luminous element layer at the time of authentication is other than white, a thickness of the first ¼ wavelength plate is T1 [um], and a thickness of the second ¼ wavelength plate is T2 [um], the first and second ¼ wavelength plates include the same material, and regularity in a case where T1 [um] is divided by 60 and regularity in a case where T2 [um] is divided by 60 are different from each other.

(18)

The electronic device according to (1) or (2), in which in a case where authentication fails, the self-luminous element layer emits light in an irradiation range further limited than the irradiation range at the time of the failed authentication according to a position in which a living body is placed.

(19)

The electronic device according to (1) or (2), in which

the imaging device includes:

a light reception unit for each pixel;

a charge accumulation unit; and

a transistor that transfers a signal charge accumulated in the light reception unit to the charge accumulation unit.

(20)

The electronic device according to either (9) or (19), in which in the imaging device, light shielding metal is arranged on the charge accumulation unit, and the light shielding metal has a pinhole shape on the light reception unit for each pixel.

(21)

The electronic device according to either (9) or (19), in which in the imaging device, light shielding metal is arranged on the charge accumulation unit, and the light shielding metal forms a wire grid type polarizer on the light reception unit for each pixel.

(22)

The electronic device according to either (9) or (19), in which in the imaging device, light shielding metal is arranged on the charge accumulation unit, and the light shielding metal has a pinhole shape on the light reception unit for each pixel and forms a wire grid type polarizer in the pinhole.

(23)

The electronic device according to (1) or (2), in which the imaging device performs authentication by a flip operation in biometric authentication.

(24)

The electronic device according to (1) or (2), further provided with: an authentication unit having a barcode reader function of authenticating a geometric shape on the basis of an image imaged by the imaging device.

(25)

The electronic device according to any one of (19) to (24), in which the authentication unit is capable of authenticating an imaging target that is moving relative to the imaging device.

### REFERENCE SIGNS LIST

1 Electronic device
1a Display screen
1b Bezel
2 Display unit
3 Camera module
4, 4a Display panel (self-luminous element layer)
4b, 6b ¼ wavelength plate
4c, 6a Polarizing plate
4d Reflector
4e Hole
5 Touch panel
6 Circularly polarizing plate
7 Cover glass
8 Imaging unit (imaging device)
9 Module lens
10 Pixel array unit
11, 12 Signal line
20 Vertical drive unit
30 Column signal processing unit
40 Control unit
46 Insulating layer
47 Tantalum oxide film
48 Hafnium oxide (HfO2) film
49 Silicon oxide film
50 First light shielding film (light shielding film)
50a Pinhole
51 Reflection layer
52 Insulating layer
53 Light absorption layer
61 Light shielding wall
61C Bank
62 Flattening film
63 Antireflection unit (moth-eye)
71 Color filter
72, 122 On-chip lens
73 Antireflection layer
100, 100a, 100b, 120 Pixel
112, 123 Semiconductor substrate
101, 124 Photoelectric conversion unit
103, 105, 106, 108 MOS transistor
107 Charge holding unit
121 n-type semiconductor region
126 Light shielding wall
127 Interlayer film
128 Photoelectric conversion element separation unit
129 Wiring layer
130 Color filter
135 Gate
138 Metal film
139 p-type well region
140 Separation region
141 Insulating film
142 Oxide film
143 Second separation region
150 Wire grid polarization element
151 Strip-shaped conductor
165 Sidewall protection layer
166 Upper protection layer
167 Adhesion layer
169 Gap
191 Insulating layer
192 Wiring layer
193 Bottom
194 Wall
195 Lid
199 Support substrate
514 Authentication unit
518 Image processing unit
1002 Signal processing unit
1004 Storage unit
1006, 1010 Authentication unit
1201 Semiconductor substrate
1210 Inner lens
1220 On-chip lens

What is claimed is:

1. An electronic device comprising:
sequentially from one side to the other side,
a first polarizing plate that makes incident light linearly polarized light;
a first ¼ wavelength plate a slow axis of which is different from an absorption axis of the first polarizing plate by 45 degrees or 135 degrees;
a self-luminous element layer;
a second ¼ wavelength plate a slow axis of which is in a same direction as the slow axis of the first ¼ wavelength plate;
a second polarizing plate an absorption axis of which is orthogonal to the absorption axis of the first polarizing plate; and
an imaging device that images light via the second polarizing plate.

2. An electronic device comprising:
sequentially from one side to the other side,
a first polarizing plate that makes incident light linearly polarized light;
a first ¼ wavelength plate an optical axis of which is different from an absorption axis of the first polarizing plate by 45 degrees or 135 degrees;
a self-luminous element layer;
a second ¼ wavelength plate an optical axis of which is different from the optical axis of the first ¼ wavelength plate by 90 degrees;
a second polarizing plate an absorption axis of which is in a same direction as the absorption axis of the first polarizing plate; and
an imaging device that images light via the second polarizing plate.

3. The electronic device according to claim 1, wherein
the second polarizing plate is provided in a pixel structure of the imaging device.

4. The electronic device according to claim 1, wherein
the self-luminous element layer is a display including a self-luminous element,
the imaging device is an imaging device that images scattered light of a finger irradiated with light of the self-luminous element via the first ¼ wavelength plate and the first polarizing plate, and images the scattered light of the finger as a fingerprint image via the first polarizing plate, the first ¼ wavelength plate, the self-luminous element layer, the second ¼ wavelength plate, and the second polarizing plate, and
the electronic device further includes:
a signal processing unit that extracts a feature point from the fingerprint image;
a storage unit that stores a feature point of a fingerprint of an authentication target; and
an authentication unit that collates the feature point extracted from the fingerprint image with the feature point of the fingerprint of the authentication target to determine whether or not the feature points coincide with each other.

5. The electronic device according to claim 1, wherein
the imaging device is an imaging device that images an authentication target irradiated with light of the self-luminous element layer via the first ¼ wavelength plate and the first polarizing plate, and images light from the authentication target via the first polarizing plate, the first ¼ wavelength plate, the self-luminous element layer, the second ¼ wavelength plate, and the second polarizing plate,
the imaging device outputs an image signal on a basis of incident light incident via an optical member with a different transmission characteristic of a wavelength, and
the electronic device further includes an authentication unit that determines that an imaging target is an artifact in a case where there is no rise in a wavelength region of 500 to 600 nanometers.

6. The electronic device according to claim 1, wherein
the imaging device is an imaging device that images an authentication target irradiated with light of the self-luminous element layer via the first ¼ wavelength plate and the first polarizing plate, and images light from the authentication target as a vein image via the first polarizing plate, the first ¼ wavelength plate, the self-luminous element layer, the second ¼ wavelength plate, and the second polarizing plate, and
the electronic device further includes:
a signal processing unit that extracts a feature point from the vein image;
a storage unit that stores a feature point of a vein of the authentication target; and
an authentication unit that collates the feature point extracted from the vein image with the feature point of the vein of the authentication target to determine whether or not the feature points coincide with each other.

7. The electronic device according to claim 1, wherein the self-luminous element layer is an organic light emitting diode.

8. The electronic device according to claim 1, wherein
the imaging device includes:
an on-chip lens; and
a metal light shielding film including a pinhole corresponding to a position in which the on-chip lens condenses light.

9. The electronic device according to claim 8, wherein
the imaging device further includes:
a metal wire grid polarization element in the pinhole.

10. The electronic device according to claim 1, wherein
the imaging device includes a pixel array including a plurality of pixels, and
a pixel includes:
a plurality of subpixels each including a photoelectric conversion element that receives light incident at a predetermined angle and outputs an analog signal on a basis of intensity of the received light; and
an on-chip lens that condenses the incident light on a subpixel.

11. The electronic device according to claim 10, wherein a metal wire grid polarization element is formed in at least one of the subpixels.

12. The electronic device according to claim 9, wherein the wire grid polarization element is a structure formed by stacking a light reflection layer including a first conductive material and a light absorption layer including a second conductive material on the light reflection layer.

13. The electronic device according to claim 1, wherein
the imaging device includes a color filter in a pixel, and
a difference between a wavelength corresponding to a spectrum center of gravity of the color filter and a wavelength corresponding to an emission spectrum center of gravity of the self-luminous element layer at the time of authentication is ±50 nm or smaller.

14. The electronic device according to claim 1, wherein
in the second polarizing plate, a reflection type polarizing filter and an absorption type polarizing filter are stacked.

15. The electronic device according to claim 1, wherein
the second polarizing plate includes a wire grid polarization element, and
is a structure formed by stacking a light reflection layer including a first conductive material and a light absorption layer including tungsten or a tungsten compound on the light reflection layer.

16. The electronic device according to claim 1, wherein in a case where a film thickness of the second ¼ wavelength plate is set to T, a refractive index of a normal light beam is set to ne, and a refractive index of an abnormal light beam is set to no, a difference between 4×T×(ne−no), which is a wavelength corresponding to the second ¼ wavelength plate, and an emission spectrum center of gravity of the self-luminous element layer at the time of authentication is 0.05 um or smaller.

17. The electronic device according to claim 1, wherein in a case where light emission of the self-luminous element layer at the time of authentication is other than white, a thickness of the first ¼ wavelength plate is T1 [um], and a thickness of the second ¼ wavelength plate is T2 [um], the first and second ¼ wavelength plates include a same material, and regularity in a case where T1 [um] is divided by 60 and regularity in a case where T2 [um] is divided by 60 are different from each other.

18. The electronic device according to claim 1, wherein,
in a case where authentication fails, the self-luminous element layer emits light in an irradiation range further limited than the irradiation range at the time of the failed authentication according to a position in which a living body is placed.

19. The electronic device according to claim 1, wherein
the imaging device includes:
a light reception unit for each pixel;
a charge accumulation unit; and
a transistor that transfers a signal charge accumulated in the light reception unit to the charge accumulation unit.

20. The electronic device according to claim 19, wherein in the imaging device, light shielding metal is arranged on the charge accumulation unit, and the light shielding metal has a pinhole shape on the light reception unit for each pixel.

21. The electronic device according to claim 19, wherein in the imaging device, light shielding metal is arranged on the charge accumulation unit, and the light shielding metal forms a wire grid type polarizer on the light reception unit for each pixel.

22. The electronic device according to claim 19, wherein in the imaging device, light shielding metal is arranged on the charge accumulation unit, and the light shielding metal has a pinhole shape on the light reception unit for each pixel and forms a wire grid type polarizer in the pinhole.

23. The electronic device according to claim 1, wherein the imaging device performs authentication by a flip operation in biometric authentication.

24. The electronic device according to claim 1, further comprising: an authentication unit having a barcode reader function of authenticating a geometric shape on a basis of an image imaged by the imaging device.

25. The electronic device according to claim 19, wherein the authentication unit is capable of authenticating an imaging target that is moving relative to the imaging device.
